(19) United States
(12) Patent Application Publication
(10) Pub. No.: US 2026/0190516 A1
(43) Pub. Date: Jul. 2, 2026

(54) DETECTION SUBSTRATE AND MANUFACTURING METHOD THEREOF, DETECTOR, IMAGING SYSTEM

(71) Applicants: BEIJING BOE SENSOR TECHNOLOGY CO., LTD., Beijing (CN); BOE TECHNOLOGY GROUP CO., LTD., Beijing (CN)

(72) Inventors: Jinyu LI, Beijing (CN); Fengchun PANG, Beijing (CN); Xuecheng HOU, Beijing (CN); Qingxin DU, Beijing (CN); Xun WANG, Beijing (CN)

(21) Appl. No.: 18/868,371

(22) PCT Filed: May 23, 2023
(86) PCT No.: PCT/CN2023/095883

§ 371 Date: Nov. 22, 2024

(51) Int. Cl. H10F 39/00; H10F 39/18

(52) U.S. Cl. CPC H10F 39/8023; H10F 39/014; H10F 39/1898; H10F 39/8037; H10F 39/805

(57) ABSTRACT

A detection substrate and a manufacturing method thereof, a detector, and an imaging system are provided. The detection substrate includes: a base substrate including a pixel setting area; and a plurality of pixel units, located in the pixel setting area; the plurality of pixel units include a marking pixel, and at least one alignment mark is arranged in the marking pixel.

### TECHNICAL FIELD

Embodiments of the present disclosure relate to a detection substrate and a manufacturing method thereof, a detector, and an imaging system.

### BACKGROUND

Cone beam computed tomography (CBCT) apparatus is an imaging apparatus which uses cone beam to irradiate and uses a computer to reconstruct tomographic image, the principle of the CBCT is that the X-ray generator performs annular digital irradiation (DR) around the irradiated object with a low amount of rays (usually the tube current is about 10 mA). Then, the data obtained in the “intersection” after digital irradiation around the irradiated object for many times (180 to 360 times, depending on different products) is “reconstructed” in the computer to obtain a three-dimensional image. The irradiation principle of obtaining the data by CBCT is completely different from that of the traditional sector scanning CT, but the algorithm principle of computer reconstruction in the later stage of the two manners is similar.

### SUMMARY

Embodiments of the present disclosure provide a detection substrate and a manufacturing method thereof, a detector, and an imaging system.

Embodiments of the present disclosure provide a detection substrate including: a base substrate including a pixel setting area; and a plurality of pixel units, located in the pixel setting area; the plurality of pixel units include a marking pixel, and at least one alignment mark is arranged in the marking pixel.

In the detection substrate provided by an embodiment of the present disclosure, the alignment mark includes a first pattern and a second pattern, and an orthographic projection of the second pattern on the base substrate overlaps with an orthographic projection of the first pattern on the base substrate.

In the detection substrate provided by an embodiment of the present disclosure, the alignment mark includes an overlay mark, the first pattern of the overlay mark is a first material layer, and the second pattern of the overlay mark is a second material layer, and materials of the first material layer and the second material layer are different.

In the detection substrate provided by an embodiment of the present disclosure, a plurality of the overlay marks are arranged in one same marking pixel, materials of the first patterns of the overlay marks are same, and materials of the second patterns of at least two overlay marks among the plurality of overlay marks are different.

In the detection substrate provided by an embodiment of the present disclosure, the plurality of overlay marks are spaced apart from each other, sequentially arranged in one direction, or arranged in an array in two directions.

In the detection substrate provided by an embodiment of the present disclosure, the detection substrate includes a gate layer, an active layer, and a source-drain layer, the active layer is located at a side of the gate layer away from the base substrate, the source-drain layer is located at a side of the active layer away from the base substrate, and the plurality of overlay marks include a first overlay mark and a second overlay mark, the first pattern of the first overlay mark is located in the gate layer, the second pattern of the first overlay mark is in a same layer as the active layer, the first pattern of the second overlay mark is located in the gate layer, and the second pattern of the second overlay mark is located in the source-drain layer.

In the detection substrate provided by an embodiment of the present disclosure, the detection substrate further includes a first passivation layer, the first passivation layer is located at a side of the source-drain layer away from the base substrate, and the plurality of overlay marks further include a third overlay mark, the first pattern of the third overlay mark is located in the gate layer, and the second pattern of the third overlay mark is a via hole in the first passivation layer.

In the detection substrate provided by an embodiment of the present disclosure, the detection substrate further includes a first passivation layer, a first electrode layer, a photoelectric sensing layer, a planarization layer, a second passivation layer, a bias voltage line layer, and a third passivation layer that are sequentially arranged; the plurality of overlay marks are located in one same marking pixel, and the plurality of overlay marks further include at least one selected from a group consisting of a third overlay mark, a fourth overlay mark, a fifth overlay mark, a sixth overlay mark, a seventh overlay mark, an eighth overlay mark, and a ninth overlay mark.

In the detection substrate provided by an embodiment of the present disclosure, the plurality of overlay marks include the third overlay mark, the fourth overlay mark, the fifth overlay mark, the sixth overlay mark, the seventh overlay mark, the eighth overlay mark, and the ninth overlay mark; the first patterns of the third overlay mark, the fourth overlay mark, the fifth overlay mark, the sixth overlay mark, the seventh overlay mark, the eighth overlay mark, and the ninth overlay mark are all located in the gate layer, the second pattern of the third overlay mark is a via hole in the first passivation layer, the second pattern of the fourth overlay mark is located in the first electrode layer, the second pattern of the fifth overlay mark is located in the photoelectric sensing layer, the second pattern of the sixth overlay mark is a via hole in the planarization layer, the second pattern of the seventh overlay mark is a via hole in the second passivation layer, the second pattern of the eighth overlay mark is located in the second electrode layer, and the second pattern of the ninth overlay mark is located in the bias voltage line layer.

In the detection substrate provided by an embodiment of the present disclosure, the detection substrate further includes a gate line and a data line, at least one of the plurality of pixel units includes a transistor, the gate line is connected with a gate electrode of the transistor, and the data line is connected with a source electrode of the transistor, the alignment mark includes at least one of a first alignment mark and a second alignment mark, in the first alignment mark, the first pattern is in a same layer as the gate line, and the data line is the second pattern, in the second alignment mark, the second pattern is in a same layer as the data line, and the gate line is the first pattern.

In the detection substrate provided by an embodiment of the present disclosure, the alignment mark further includes a third alignment mark, and an orthographic projection of the second pattern of the third alignment mark on the base substrate is within an orthographic projection of the first pattern of the third alignment mark on the base substrate.

In the detection substrate provided by an embodiment of the present disclosure, the alignment mark further includes a stitch mark, the first pattern of the stitch mark is an alignment material layer, and the second pattern of the stitch mark is a hollow area.

In the detection substrate provided by an embodiment of the present disclosure, the stitch mark includes a first stitch mark, a second stitch mark and a third stitch mark, the first stitch mark is located in the gate layer, the second stitch mark is in a same layer as the active layer, and the third stitch mark is located in the source-drain layer.

In the detection substrate provided by an embodiment of the present disclosure, the marking pixel includes a first marking pixel, the stitch mark is located in the first marking pixel, the marking pixel includes a second marking pixel, the overlay mark is located in the second marking pixel, and the first marking pixel and the second marking pixel are adjacent to each other.

In the detection substrate provided by an embodiment of the present disclosure, the marking pixel includes a first marking pixel, the stitch mark is located in the first marking pixel, the marking pixel includes a second marking pixel, the overlay mark is located in the second marking pixel, the first marking pixel and the second marking pixel are spaced apart from each other, the plurality of pixel units include a plurality of non-marking pixels, and at least one of the plurality of non-marking pixels is arranged between the first marking pixel and the second marking pixel.

In the detection substrate provided by an embodiment of the present disclosure, the first pattern and the second pattern have a first boundary distance and a second boundary distance in a first direction, the first direction is parallel with the base substrate, a ratio of the first boundary distance to a larger one of a size of the first pattern in the first direction and a size of the second pattern in the first direction is less than or equal to ⅓, and a ratio of the second boundary distance to the larger one of the size of the first pattern in the first direction and the size of the second pattern in the first direction is less than or equal to ⅓, a ratio of the first boundary distance to the larger one of the size of the first pattern in the first direction and the size of the second pattern in the first direction is greater than or equal to ¼, and a ratio of the second boundary distance to the larger one of the size of the first pattern in the first direction and the size of the second pattern in the first direction is greater than or equal to ¼.

In the detection substrate provided by an embodiment of the present disclosure, an orthographic projection of the second pattern on the base substrate is within an orthographic projection of the first pattern on the base substrate.

In the detection substrate provided by an embodiment of the present disclosure, the first pattern and the second pattern have a third boundary distance and a fourth boundary distance in a second direction, the second direction is parallel with the base substrate and intersects with the first direction, and a ratio of the third boundary distance to a size of the first pattern in the second direction is less than or equal to ⅓, and a ratio of the fourth boundary distance to the size of the first pattern in the second direction is less than or equal to ⅓, the first pattern and the second pattern have a third boundary distance and a fourth boundary distance in the second direction, a ratio of the third boundary distance to the size of the first pattern in the second direction is greater than or equal to ¼, and a ratio of the fourth boundary distance to the size of the first pattern in the second direction is greater than or equal to ¼.

In the detection substrate provided by an embodiment of the present disclosure, at least two alignment marks are arranged in one same marking pixel, and the two alignment marks are spaced apart from each other.

In the detection substrate provided by an embodiment of the present disclosure, the plurality of pixel units include a plurality of photosensitive pixels and a plurality of positioning pixels, at least one marking pixel in the plurality of marking pixels is adjacent to at least one photosensitive pixel in the plurality of photosensitive pixels, and the plurality of marking pixels include at least one positioning pixel in the plurality of positioning pixels and/or at least one photosensitive pixel in the plurality of photosensitive pixels.

In the detection substrate provided by an embodiment of the present disclosure, the plurality of positioning pixels include a non-photosensitive pixel.

In the detection substrate provided by an embodiment of the present disclosure, each of the plurality of positioning pixels is configured to have a fixed gray scale, and the fixed gray scale does not change with real-time change of incident light.

In the detection substrate provided by an embodiment of the present disclosure, the photosensitive pixel includes a first transistor, a first photoelectric sensing device, and a first bias voltage line, a first electrode of the first photoelectric sensing device is electrically connected with the first transistor, and a second electrode of the first photoelectric sensing device is electrically connected with the first bias voltage line.

In the detection substrate provided by an embodiment of the present disclosure, each of the plurality of positioning pixels includes a second transistor, or each of the plurality of positioning pixels includes a second transistor, a second photoelectric sensing device and a second bias voltage line, a first electrode of the second photoelectric sensing device is connected with the second transistor, and a second electrode of the second photoelectric sensing device is not electrically connected with the second bias voltage line.

In the detection substrate provided by an embodiment of the present disclosure, each of the plurality of positioning pixels includes a third transistor, a connection electrode, and a second bias voltage line, and the second bias voltage line is electrically connected with the third transistor through the connection electrode.

Embodiments of the present disclosure further provide a detector, including any one of the detection substrates as described above.

Embodiments of the present disclosure further provide an imaging system, including any one of the detectors as described above.

Embodiments of the present disclosure further provide a manufacturing method of a detection substrate, including: forming a plurality of pixel units in a pixel setting area of a base substrate; the plurality of pixel units include a marking pixel, and at least one alignment mark is arranged in the marking pixel.

In the manufacturing method of the detection substrate provided by an embodiment of the present disclosure, forming the alignment mark includes: forming a first pattern and forming a second pattern; an orthographic projection of the second pattern on the base substrate overlaps with an orthographic projection of the first pattern on the base substrate.

In the manufacturing method of the detection substrate provided by an embodiment of the present disclosure, the first pattern is closer to the base substrate than the second pattern, the manufacturing method includes: performing a threshold comparison which includes: detecting whether a first boundary distance and a second boundary distance of the first pattern and the second pattern in a first direction are within a first threshold range, and/or detecting whether a third boundary distance and a fourth boundary distance of the first pattern and the second pattern in a second direction are within a second threshold range, if yes, continuing subsequent processes, otherwise, removing the second pattern and forming a new second pattern; and continuously repeating a step of the threshold comparison for the first pattern and the new second pattern.

In the manufacturing method of the detection substrate provided by an embodiment of the present disclosure, the second pattern is a photoresist layer.

In the manufacturing method of the detection substrate provided by an embodiment of the present disclosure, the manufacturing method further includes forming a data line and forming a gate line, forming the plurality of pixel units includes forming a transistor, and the gate line is connected with a gate electrode of the transistor, and the data line is connected with a source electrode of the transistor, the alignment mark includes at least one of a first alignment mark and a second alignment mark, in the first alignment mark, the first pattern is in a same layer as the gate line, and the data line is the second pattern, in the second alignment mark, the second pattern is in a same layer as the data line, and the gate line is the first pattern.

In the manufacturing method of the detection substrate provided by an embodiment of the present disclosure, the first pattern and the second pattern have a first boundary distance and a second boundary distance in a first direction, a ratio of the first boundary distance to a larger one of a size of the first pattern in the first direction and a size of the second pattern in the first direction is less than or equal to ⅓, and a ratio of the second boundary distance to the larger one of the size of the first pattern in the first direction and the size of the second pattern in the first direction is less than or equal to ⅓, a ratio of the first boundary distance to the larger one of the size of the first pattern in the first direction and the size of the second pattern in the first direction is greater than or equal to ¼, and a ratio of the second boundary distance to the larger one of the size of the first pattern in the first direction and the size of the second pattern in the first direction is greater than or equal to ¼.

In the manufacturing method of the detection substrate provided by an embodiment of the present disclosure, the first pattern and the second pattern have a third boundary distance and a fourth boundary distance in a second direction, a ratio of the third boundary distance to a size of the first pattern in the second direction is less than or equal to ⅓, and a ratio of the fourth boundary distance to the size of the first pattern in the second direction is less than or equal to ⅓, the first pattern and the second pattern have a third boundary distance and a fourth boundary distance in the second direction, a ratio of the third boundary distance to the size of the first pattern in the second direction is greater than or equal to ¼, and a ratio of the fourth boundary distance to the size of the first pattern in the second direction is greater than or equal to ¼.

In the manufacturing method of the detection substrate provided by an embodiment of the present disclosure, forming the plurality of pixel units includes forming a plurality of photosensitive pixels and forming a plurality of positioning pixels, at least one marking pixel in the plurality of marking pixels is adjacent to at least one photosensitive pixel in the plurality of photosensitive pixels, and the plurality of marking pixels include at least one positioning pixel in the plurality of positioning pixels and/or at least one photosensitive pixel in the plurality of photosensitive pixels.

In the manufacturing method of the detection substrate provided by an embodiment of the present disclosure, the first pattern is formed in a same layer as one component in the marking pixel, and the second pattern is formed in a same layer as another component in the marking pixel.

### BRIEF DESCRIPTION OF DRAWINGS

In order to clearly illustrate the technical solution of the embodiments of the present disclosure, the drawings of the embodiments will be briefly described in the following; it is obvious that the described drawings are only related to some embodiments of the present disclosure and thus are not construed as any limitation to the present disclosure.

FIG. 1 is a schematic plan view of a detection substrate provided by an embodiment of the present disclosure.

FIG. 2 is a schematic plan view of a detection substrate provided by another embodiment of the present disclosure.

FIG. 3 is a schematic plan view of a detection substrate provided by another embodiment of the present disclosure.

FIG. 4 is a schematic plan view of a detection substrate provided by another embodiment of the present disclosure.

FIG. 5 is a layout diagram of a photosensitive pixel in a detection substrate provided by an embodiment of the present disclosure.

FIG. 6 is a sectional view taken along the line C1-C2 in FIG. 5.

FIG. 7 is a sectional view taken along the line C3-C4 in FIG. 5.

FIG. 8 is a layout diagram of a normally black pixel in a detection substrate provided by an embodiment of the present disclosure.

FIG. 9 is a layout diagram of a normally black pixel with overlay marks in a detection substrate provided by an embodiment of the present disclosure.

FIG. 10 is a sectional view taken along the line A1-A2 in FIG. 9.

FIG. 11 is a sectional view taken along the line A3-A4 in FIG. 9.

FIG. 12 is a sectional view taken along the line A5-A6 in FIG. 9.

FIG. 13 is a sectional view taken along the line A7-A8 in FIG. 9.

FIG. 14 is a plan view of a gate layer LY1 in FIG. 9.

FIG. 15A is a schematic diagram of forming a target film and forming a photoresist pattern on the target film.

FIG. 15B is a plan view of the gate layer LY1 and a semiconductor layer SC in FIG. 9.

FIG. 16 is a layout diagram of a normally white pixel in a detection substrate provided by an embodiment of the present disclosure.

FIG. 17 is a layout diagram of a normally white pixel with overlay marks in a detection substrate provided by an embodiment of the present disclosure.

FIG. 18 is a layout diagram of a normally black pixel with stitch marks in a detection substrate provided by an embodiment of the present disclosure.

FIG. 19A is a plan view of a photoresist pattern of a photoresist layer after a first exposure in forming the detection substrate shown in FIG. 18.

FIG. 19B is a plan view of a photoresist pattern of the photoresist layer after a second exposure in forming the detection substrate shown in FIG. 18.

FIG. 19C is a plan view of a structure obtained by etching a material film using the photoresist pattern shown in FIG. 18 as a mask.

FIG. 20 is a layout diagram of a normally white pixel with stitch marks in a detection substrate provided by an embodiment of the present disclosure.

FIG. 21 is a layout diagram of a photosensitive pixel with overlay marks in a detection substrate provided by an embodiment of the present disclosure.

FIG. 22 is a layout diagram of a photosensitive pixel with stitch marks in a detection substrate provided by an embodiment of the present disclosure.

FIG. 23 is a layout diagram of a photosensitive pixel with overlay marks in a detection substrate provided by an embodiment of the present disclosure.

FIG. 24 is a layout diagram of a photosensitive pixel with overlay marks in a detection substrate provided by an embodiment of the present disclosure.

FIG. 25 is a layout diagram of a photosensitive pixel with overlay marks in a detection substrate provided by an embodiment of the present disclosure.

FIG. 26 is a plan view of another overlay mark in a detection substrate provided by an embodiment of the present disclosure.

FIG. 27 is a plan view of another stitch mark in a detection substrate provided by an embodiment of the present disclosure.

FIG. 28 is a schematic diagram of an imaging system provided by an embodiment of the present disclosure.

### DETAILED DESCRIPTION

In order to make objects, technical details and advantages of the embodiments of the present disclosure more clear, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly.

X-ray detector is an X-ray image detector with a photodiode array as the core, under X-ray irradiation, the scintillator or phosphor layer of the detector converts X-ray photons into visible light, and then an array with the function of the photodiode receives the visible light to output image electrical signals, and the image electrical signals are transmitted through peripheral circuits and converted through analog-digital, thus obtaining digital images. Because it has gone through the imaging process of X-ray-visible light-charge image-digital image in the X-ray detector, the X-ray detector is often called indirect conversion flat panel detector. For example, the photodiode includes amorphous silicon, but is not limited thereto.

Because of the need for dynamic real-time scanning, the accurate positioning of the scanned part becomes very important. By setting the pixel combination of normally black pixels and normally white pixels which can be used for algorithm capture, and thus then the accurate positioning of the image can be realized.

In the case where the back plate of the X-ray detector is produced by using a small-size exposure machine, if the size of back plate to be produced is larger than the size of the mask, it is often necessary to perform multiple stitch exposures to form a complete circuit structure, and precision control in stitch exposure is very important. In a general detector, all the pixels in the pixel setting area are effective pixels, and there is no space to arrange alignment marks, which leads to the stitch accuracy and alignment accuracy of the pixel setting area cannot be monitored, thereby leading to the image quality problem of uneven gray level of the image on the final product.

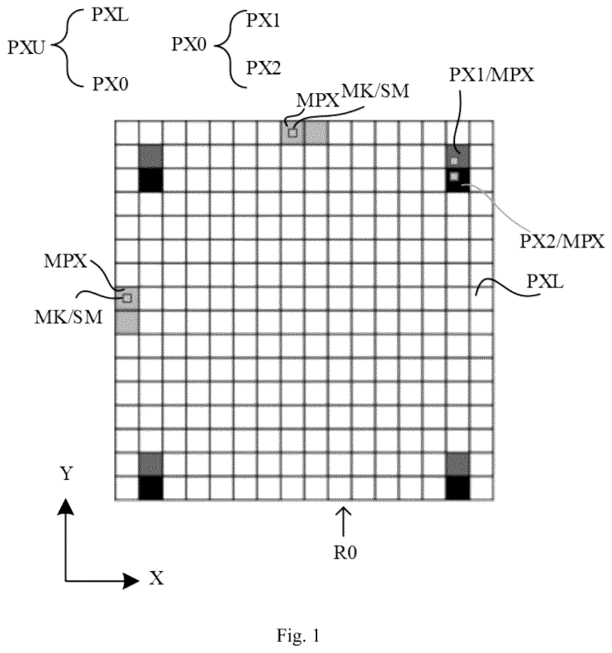

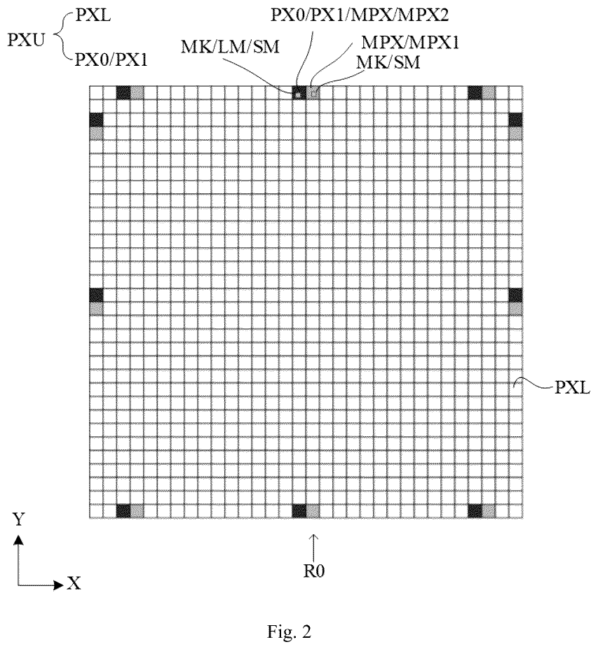

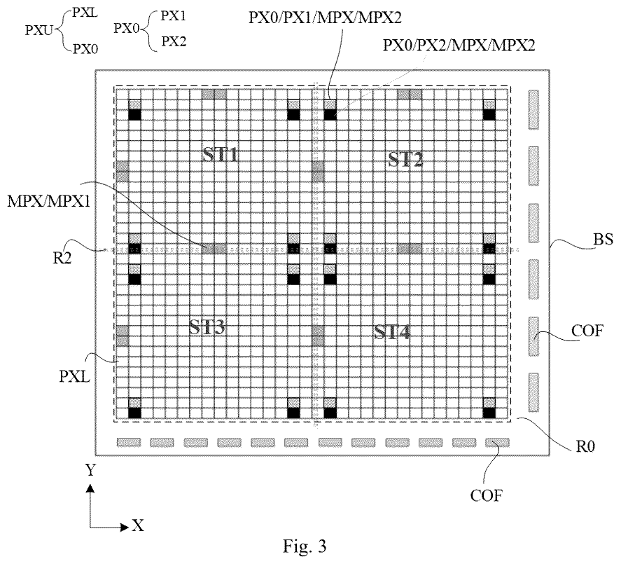

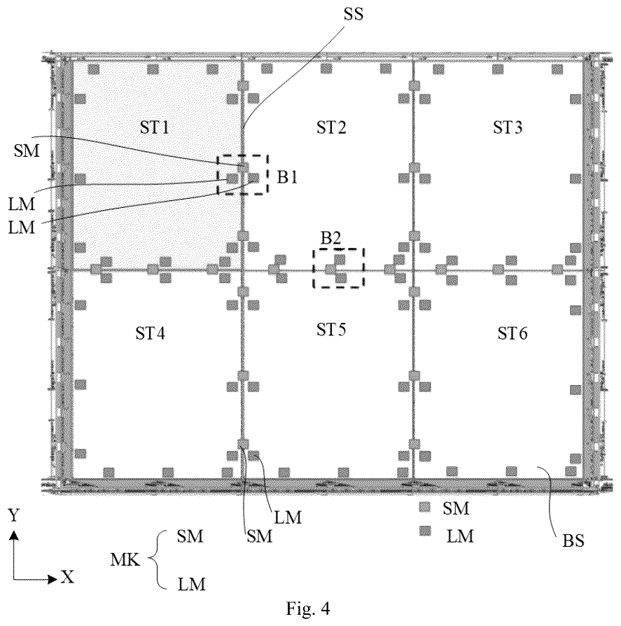

FIG. 1 is a schematic plan view of a detection substrate provided by an embodiment of the present disclosure. FIG. 2 is a schematic plan view of a detection substrate provided by another embodiment of the present disclosure. FIG. 3 is a schematic plan view of a detection substrate provided by another embodiment of the present disclosure. FIG. 4 is a schematic plan view of a detection substrate provided by another embodiment of the present disclosure.

As shown in FIG. 1 to FIG. 4, an embodiment of the present disclosure provides a detection substrate, the detection substrate includes a base substrate BS and a plurality of pixel units PXU. The base substrate BS includes a pixel setting area R0, and the plurality of pixel units PXU are located in the pixel setting area R0.

As shown in FIG. 1 to FIG. 4, the plurality of pixel units PXU include at least one marking pixel MPX. At least one alignment mark MK is arranged in the marking pixel MPX.

An embodiment of the present disclosure provides a detection substrate, in which at least one alignment mark MK is arranged in the marking pixel MPX, which is beneficial to improving the alignment accuracy in the manufacturing process of the detection substrate and to improving the uniformity of the image quality of the final product.

As shown in FIG. 1 to FIG. 4, the plurality of pixel units PXU include a plurality of photosensitive pixels PXL and a plurality of positioning pixels PX0, the plurality of photosensitive pixels PXL are located in the pixel setting area R0, the plurality of positioning pixels PX0 are located in the pixel setting area R0, and at least one positioning pixel PX0 among the plurality of positioning pixels PX0 is adjacent to at least one photosensitive pixel PXL among the plurality of photosensitive pixels PXL.

For example, as shown in FIG. 1 to FIG. 3, the marking pixel MPX includes at least one positioning pixel among the plurality of positioning pixels PX0 and/or at least one photosensitive pixel among the plurality of photosensitive pixels PXL.

As shown in FIG. 1 to FIG. 4, an alignment mark MK is provided in at least one selected from a group consisting of the plurality of positioning pixels PX0 and the plurality of photosensitive pixels PXL.

In the detection substrate provided by the embodiment of the present disclosure, an alignment mark MK is arranged in at least one of the plurality of marking pixels MPX (for example, an alignment mark MK is arranged in at least one selected from a group consisting of the plurality of positioning pixels PX0 and the plurality of photosensitive pixels PXL), so as to facilitate monitoring the stitch accuracy and/or the alignment accuracy in the manufacturing process of the detection substrate, improve the alignment accuracy in the process, weaken the problem that the stitch exposure pixel setting area cannot achieve overlay compensation and/or the stitch accuracy cannot be controlled, and avoid the problem of uneven gray scale of the image in the final product, and improve the uniformity of image quality of the final product.

In the embodiment of the present disclosure, the marking pixel MPX is a pixel unit in which the alignment mark MK is arranged. For example, in some embodiments, one or several photosensitive pixels PXL are selected as the marking pixels MPX. For example, in other embodiments, the detection substrate has positioning pixel(s) PX0, and one or several positioning pixels PX0 are selected as the marking pixels MPX. For example, in other embodiments, the detection substrate has positioning pixel(s) PX0, one or several photosensitive pixels PXL are selected as the marking pixels MPX, and one or several positioning pixels PX0 are selected as the marking pixels MPX.

As shown in FIG. 1 to FIG. 4, the photosensitive pixel PXL may be called a pixel unit PXU, the positioning pixel PX0 can be also called a pixel unit PXU, and the detection substrate includes a plurality of pixel units PXU which are arranged in an array.

The alignment mark MK in the marking pixel MPX is omitted in FIG. 3. FIG. 3 shows four exposure areas ST1 to ST4. FIG. 4 shows six exposure areas ST1 to ST6. Each exposure area is provided with a plurality of photosensitive pixels and a plurality of marking pixels. FIG. 4 shows the alignment mark MK, but does not show the photosensitive pixels PXL and the marking pixels MPX. FIG. 1 and FIG. 2 show only one exposure area. FIG. 3 further shows the chip on film COF.

For example, the stitch exposure process includes the following steps: forming a target film, forming a photoresist layer on the target film, exposing the photoresist layer for several times to form a photoresist pattern, and etching the target film with the photoresist pattern as a mask to form a target pattern. For example, the detection substrate shown in FIG. 3 may be exposed in sequence for the exposure area ST1, the exposure area ST2, the exposure area ST3 and the exposure area ST4, that is, the detection substrate may be exposed in four times. For example, the detection substrate shown in FIG. 4 may be exposed in sequence for the exposure area ST1, the exposure area ST2, the exposure area ST3, the exposure area ST4, the exposure area ST5, and the exposure area ST6, that is, exposed in six times.

FIG. 3 shows a two-time exposure area R2. The two-time exposure area R2 is an area that is exposed twice in the exposure process of two adjacent exposure areas. That is, the overlapping area of the two exposure areas.

For example, each of the plurality of photosensitive pixels PXL includes a photoelectric sensing device, the photoelectric sensing device is configured to convert incident light into electrical signals so that the photosensitive pixel in which the photoelectric sensing device is located generates a gray scale that changes with the real-time change of the incident light, and thereby a charge image can be generated.

Under the irradiation of light, light passing through the object to be imaged enters the flat panel detector, and then the light signal of the incident light is converted into an image electrical signal by the photosensitive element (photoelectric sensing device) of the flat panel detector, thereby generating a charge image. In this process, in the case where the position where the incident light is incident onto the flat panel detector moves, the incident light is received by the flat panel detector and different charge images are generated in different positions in response to the incident light, and the positions of these charge images are located in different areas. Later, it is required to synthesize the final image by using multiple real-time charge images obtained with the real-time movement of the incident light, and in this process, it is required to synthesize the final image by using the position information of the multiple real-time charge images, and it is required that the multiple real-time charge images are all located in a preset area in order to synthesize an ideal final image.

For example, in the detection substrate, the marking pixel MPX includes a non-photosensitive pixel.

For example, as shown in FIG. 1 to FIG. 3, in the detection substrate, the positioning pixel PX0 (non-photosensitive pixel) includes at least one of a normally white pixel PX1 and a normally black pixel PX2.

For example, in the detection substrate, the positioning pixel PX0 is configured to have a fixed gray scale that does not change with the real-time change of the incident light.

The detection substrate provided by the embodiment of the present disclosure is provided with positioning pixels PX0 having a fixed gray scale, so that a plurality of positioning pixels can be identified, and position information of the positioning pixels, such as coordinates, can be obtained, and the position of the charge image generated by the detection substrate (detector) can be determined by taking the coordinates of the positioning pixels as a reference.

According to the detection substrate provided by the embodiment of the present disclosure, the positioning pixel PX0 can be used for positioning. Because positioning pixel PX0 is arranged, it is beneficial to accurately positioning the image, improving the accuracy of imaging, reducing the interference of artifacts, which lays a foundation for subsequent image processing.

For example, the gray scale of the normally white pixel PX1 is different from that of the normally black pixel PX2. For example, the gray scale of the normally white pixel PX1 is larger than that of the normally black pixel PX2.

For example, the normally black pixel PX2 is always in a black state. For example, the normally white pixel PX1 is always bright, for example, the brightness is always the highest brightness that can be achieved. In this way, when the flat panel detector is in a black state as a whole, the normally white pixel PX1 can be accurately identified; when the flat panel detector is in a bright state as a whole, it can accurately identify the normally black pixel PX2 which is always dark. That is, no matter whether the flat panel detector is in a black state or a bright state as a whole, the accurate positioning effect can be achieved.

As shown in FIG. 1 to FIG. 4, the alignment mark MK may include at least one of a stitch mark SM and an overlay mark LM. The stitch mark SM is arranged to monitor the stitch accuracy in the manufacturing process of the detection substrate, and the overlay mark LM is arranged to monitor the alignment accuracy in the manufacturing process of the detection substrate.

FIG. 4 shows a frame B1 and a frame B2, a stitch mark SM and an overlay mark LM are arranged in each of the frame B1 and the frame B2, and the stitch mark SM is arranged at the stitch seam SS, and the two overlay marks LM are respectively arranged at two sides of the stitch seam SS.

FIG. 3 and FIG. 4 are illustrated by taking the case that the stitch seam SS is a straight line as an example, however, the embodiments of the present disclosure are not limited to this case. For example, the stitch seam SS may be bent at the stitch mark.

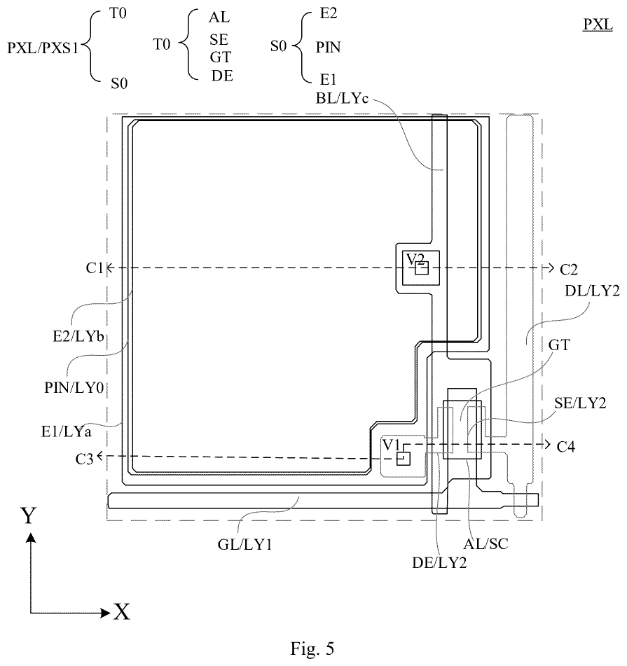

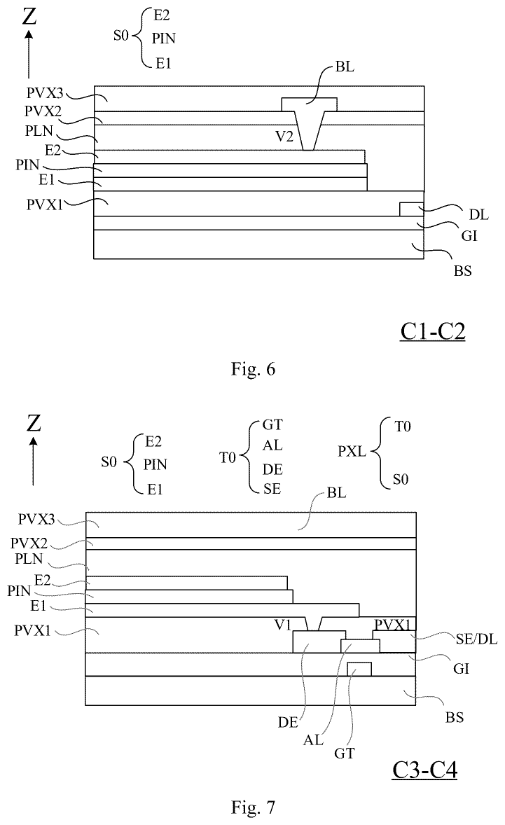

FIG. 5 is a layout diagram of a photosensitive pixel in a detection substrate provided by an embodiment of the present disclosure. FIG. 6 is a sectional view taken along the line C1-C2 in FIG. 5. FIG. 7 is a sectional view taken along the line C3-C4 in FIG. 5.

As shown in FIG. 5 to FIG. 7, the photosensitive pixel PXL includes a transistor T0 and a photoelectric sensing device S0.

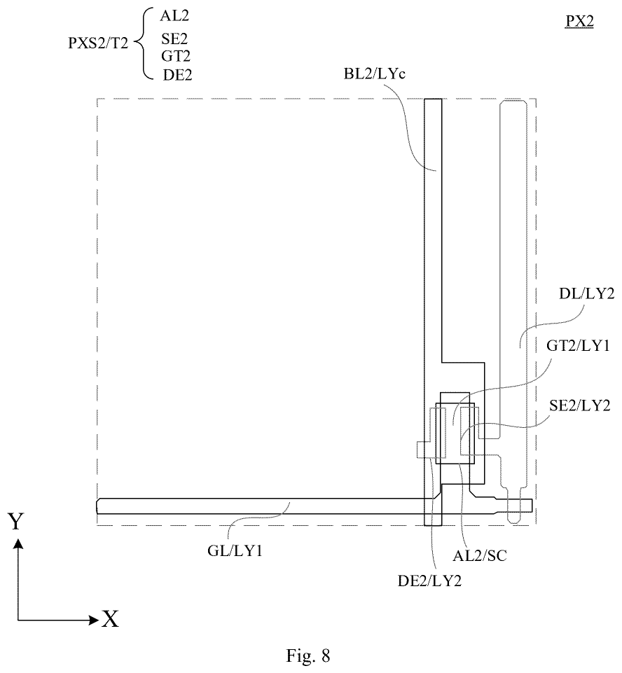

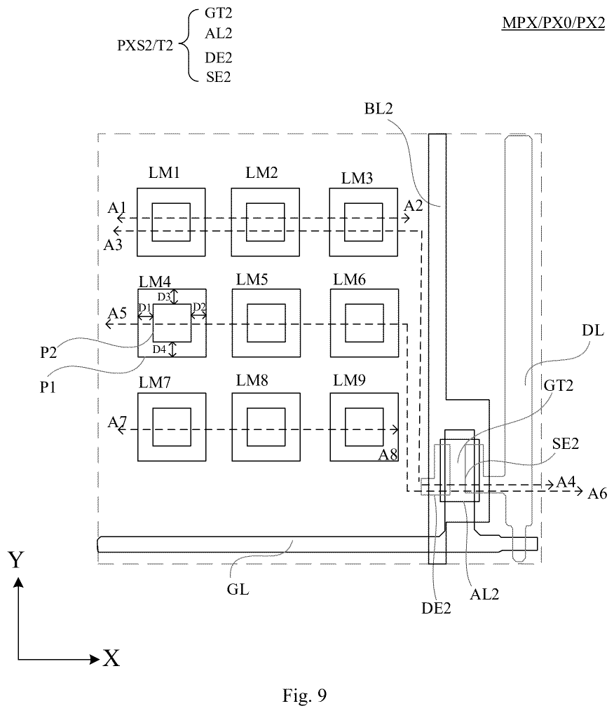

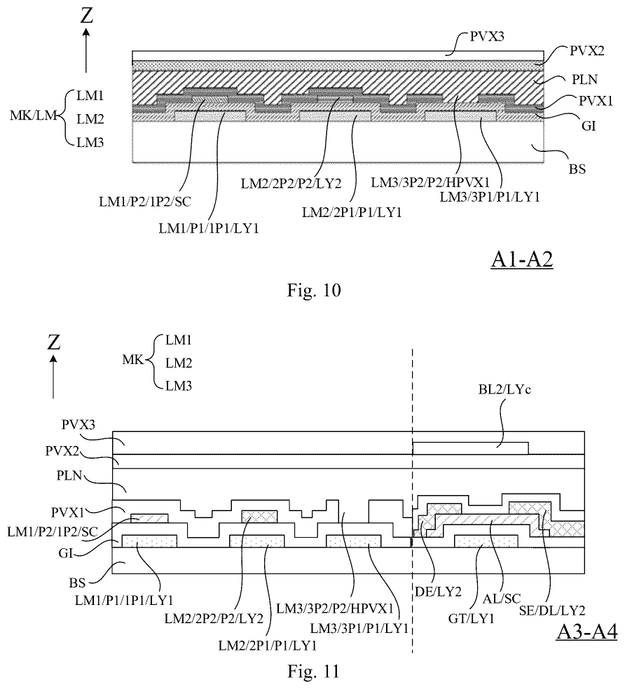

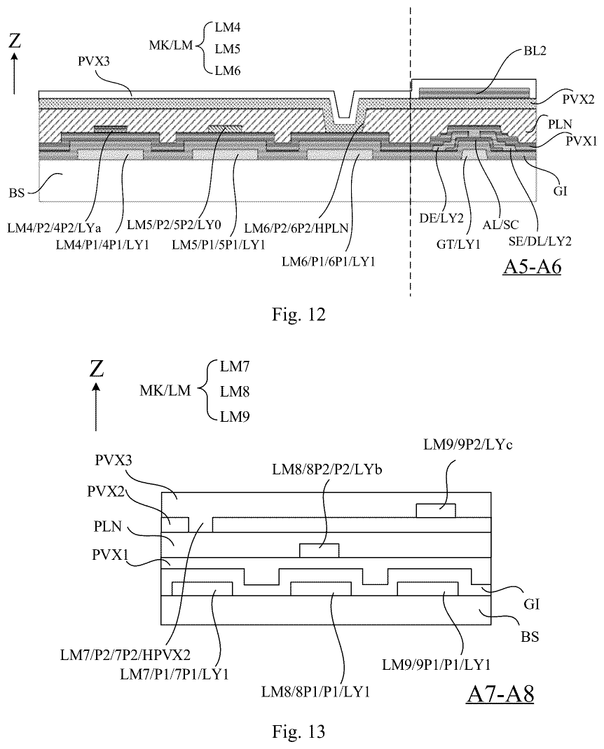

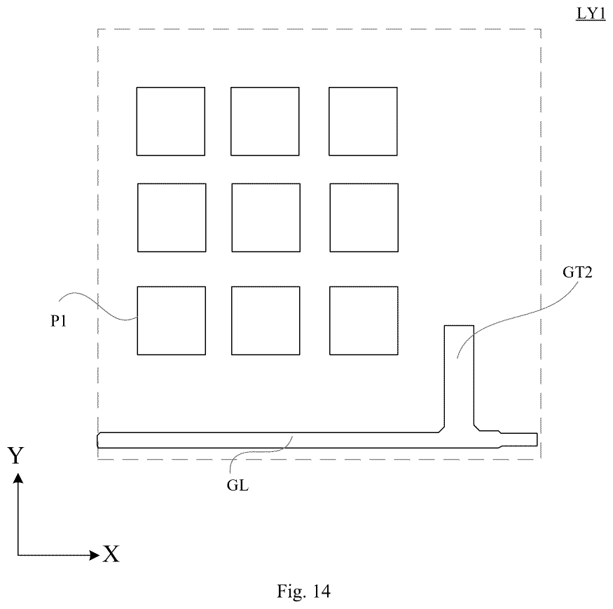

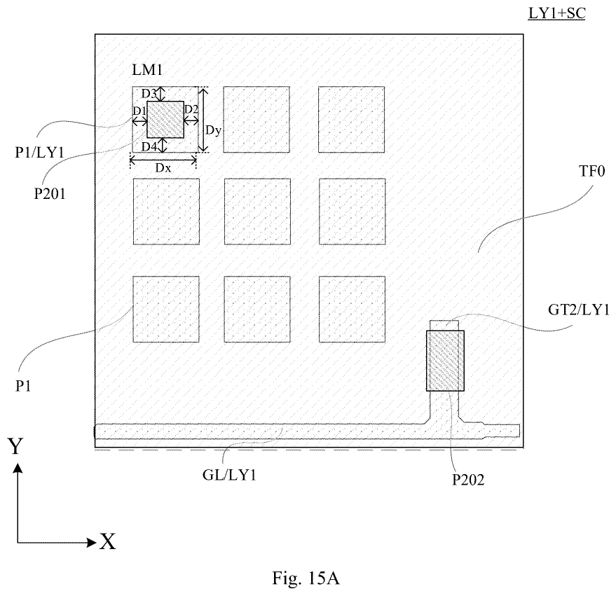

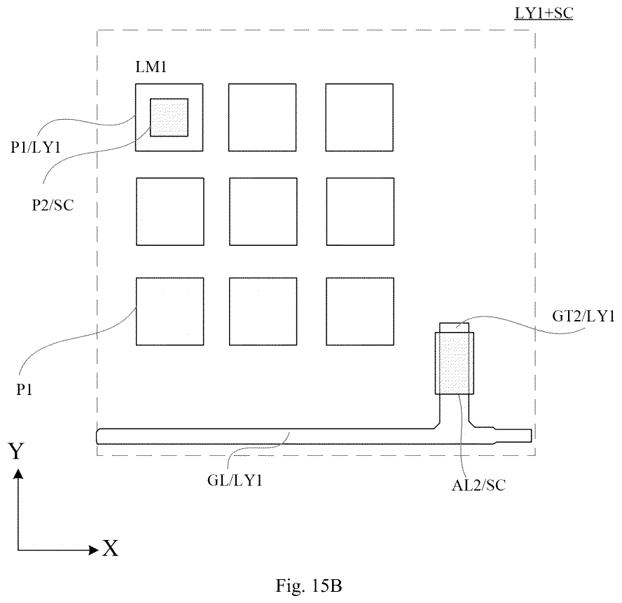

FIG. 8 is a layout diagram of a normally black pixel in a detection substrate provided by an embodiment of the present disclosure. FIG. 9 is a layout diagram of a normally black pixel with overlay marks in a detection substrate provided by an embodiment of the present disclosure. FIG. 10 is a sectional view taken along the line A1-A2 in FIG. 9. FIG. 11 is a sectional view taken along the line A3-A4 in FIG. 9. FIG. 12 is a sectional view taken along the line A5-A6 in FIG. 9. FIG. 13 is a sectional view taken along the line A7-A8 in FIG. 9. FIG. 14 is a plan view of a gate layer LY1 in FIG. 9. FIG. 15A is a schematic diagram of forming a target film and forming a photoresist pattern on the target film. FIG. 15B is a plan view of the gate layer LY1 and a semiconductor layer SC in FIG. 9.

As shown in FIG. 8 to FIG. 15B, the normally black pixel PX2 includes a transistor T1. FIG. 9 shows nine alignment marks MK located in the normally black pixel PX2, all of the nine alignment marks MK are overlay marks LM. The normally black pixel PX2 may not be provided with the photoelectric sensing device S0, or, the photoelectric sensing device S0 may not be connected with the transistor T1. The alignment mark MK includes a first pattern P1 and a second pattern P2.

The overlay mark LM is used to monitor the alignment accuracy between different films in the same one exposure area. By monitoring the sizes of distances of the respective boundaries of the first pattern and the second pattern at the top, the bottom, the left and the right, the alignment deviation between these two layers can be obtained, and the alignment deviation between these two layers can meet the design requirements through parameter compensation.

FIG. 14 shows a plan view of the gate layer LY1 in FIG. 9. As shown in FIG. 14, the gate layer LY1 includes a gate line GL, a gate electrode GT2, and first patterns P1 of the nine alignment marks MK (overlay marks LM). As shown in FIG. 14, the gate line GL and the gate electrode GT2 are of an integral structure.

As shown in FIG. 15A and FIG. 15B, the exposure process of the detection substrate includes the following steps.

Step 1) forming a target film TF0 on the gate layer LY1, and forming a photoresist film on the target film TF0.

Step 2) exposing the photoresist film to form an exposed photoresist film, the exposed photoresist film includes a pattern P201 and a pattern P202.

Step 3) checking whether the pattern P201 and the first pattern P1 meet the requirements, if not, removing the photoresist film and preparing a photoresist film again, if yes, proceeding to the next step.

Step 4) developing the exposed photoresist film to form a photoresist pattern in which the pattern P201 and the pattern P202 are reserved, and etching the target film TF0 by using the photoresist pattern as a mask to form a target pattern, the target pattern includes a second pattern P2 and an active layer AL2.

FIG. 15B shows a plan view of the gate layer LY1 and the semiconductor layer SC in FIG. 9. As shown in FIG. 15B, the semiconductor layer SC includes the active layer AL2 and the second pattern P2 of the overlay mark LM1. That is, the second pattern P2 of the overlay mark LM1 is formed in the same one process of forming the active layer AL2.

The second patterns P2 of the overlay marks LM except the overlay mark LM1 shown in FIG. 9 are also formed synchronously in the process of forming the components of the photosensitive pixel and the marking pixel, in a manner similar to the second pattern P2 of the overlay mark LM1. For each overlay mark LM, reference can be made to the layout diagram shown in FIG. 9 and the cross-sectional views shown in FIG. 10 to FIG. 13.

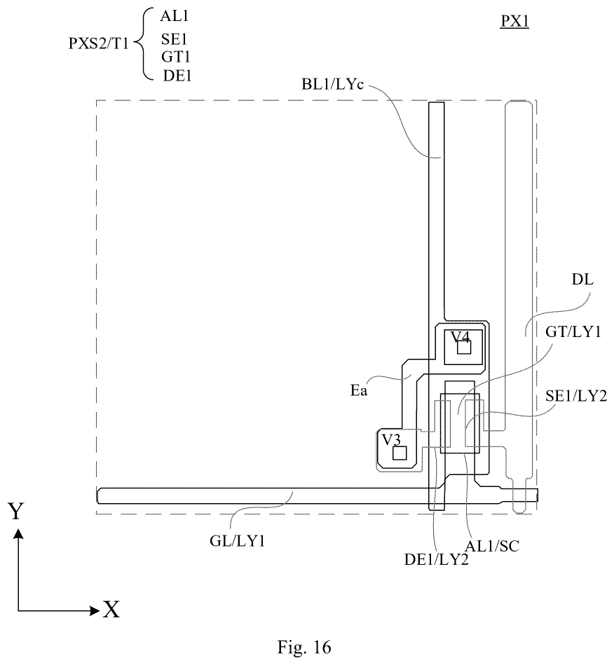

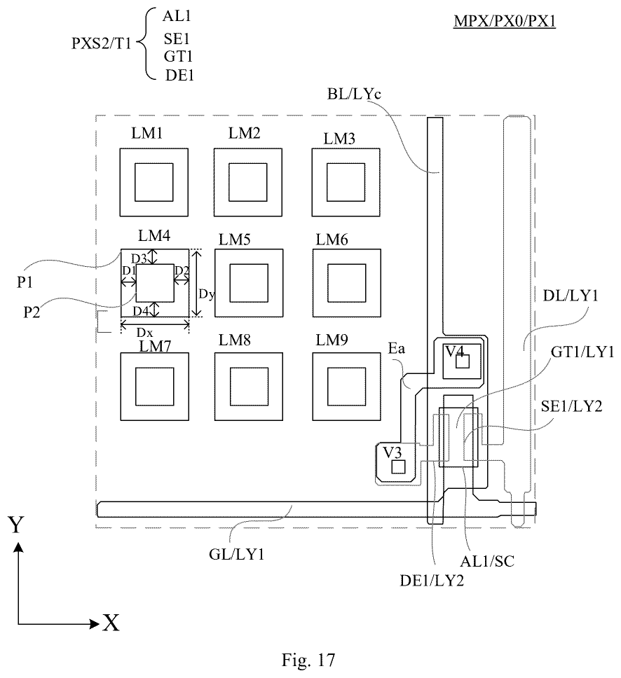

FIG. 16 is a layout diagram of a normally white pixel in a detection substrate provided by an embodiment of the present disclosure. FIG. 17 is a layout diagram of a normally white pixel with overlay marks in a detection substrate provided by an embodiment of the present disclosure.

The overlay mark LM in FIG. 17 can be referred to the overlay mark LM shown in FIG. 9. For FIG. 9, the nine overlay marks LM are arranged in the normally black pixel PX2. While FIG. 17 shows that nine overlay marks LM are arranged in the normally white pixel PX1.

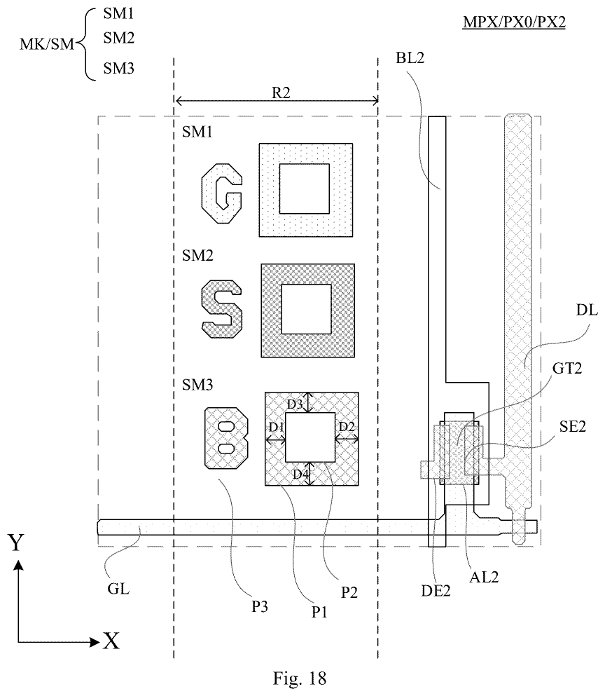

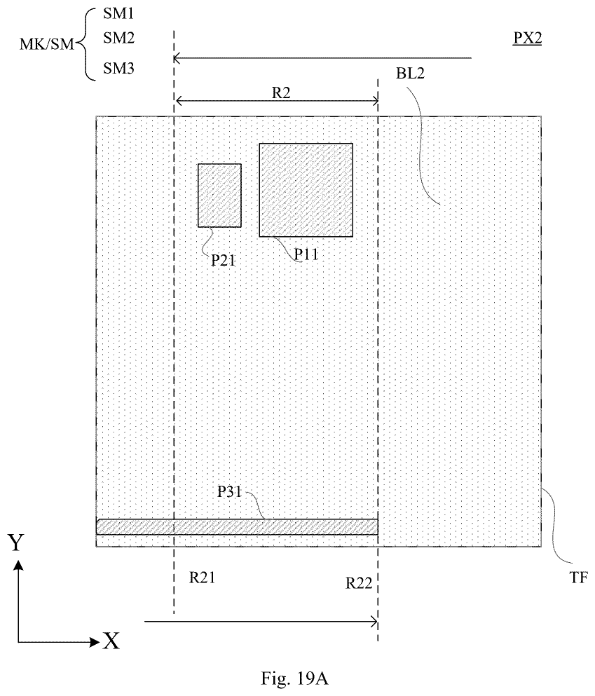

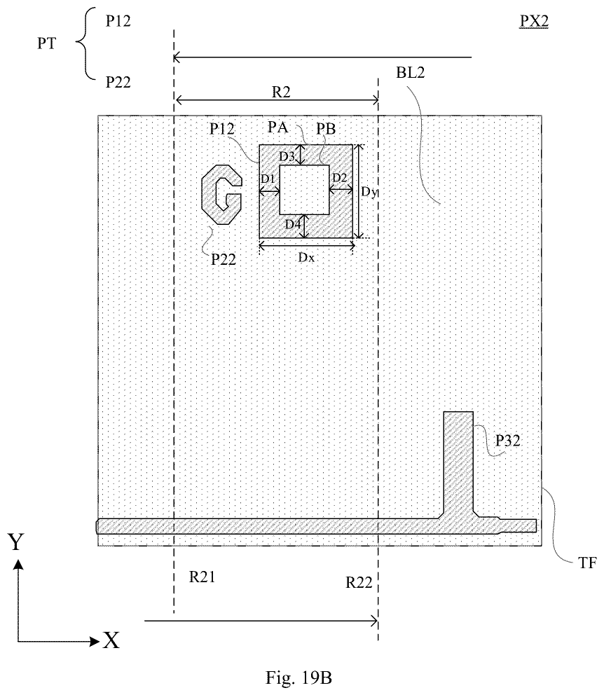

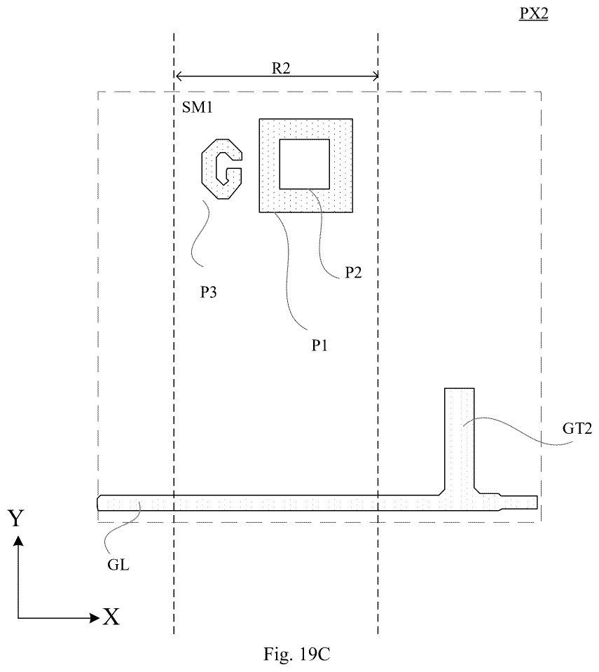

FIG. 18 is a layout diagram of a normally black pixel with stitch marks in a detection substrate provided by an embodiment of the present disclosure. FIG. 19A is a plan view of a photoresist pattern of a photoresist layer after a first exposure in forming the detection substrate shown in FIG. 18. FIG. 19B is a plan view of a photoresist pattern of the photoresist layer after a second exposure in forming the detection substrate shown in FIG. 18. FIG. 19C is a plan view of a structure obtained by etching a material film using the photoresist pattern shown in FIG. 18 as a mask.

As shown in FIG. 18, the stitch mark SM is arranged in the normally black pixel PX2. FIG. 18 illustrates an example in which three stitch marks SM are arranged in one normally black pixel PX2.

As shown in FIG. 18, the normally black pixel PX2 has no photoelectric sensing device. The stitch mark SM is formed by overlaying patterns formed by two exposures.

The stitch mark SM is used to monitor the stitch accuracy between different exposure areas. The stitch mark SM is used to monitor the stitch accuracy between two adjacent exposure areas.

By measuring the sizes of the distances between the respective boundaries of the first pattern and the second pattern at the top, the bottom, the left and the right, the stitch alignment accuracy of the two exposures can be monitored, and the parameter compensation can be carried out according to the measurement, so that the stitch accuracy of the stitch exposure can be improved, and the uniformity of the image quality of the product can be further improved.

FIG. 19A shows a two-time exposure area R2 with a boundary R21 and a boundary R22. The right boundary of the exposure area on the left is the boundary R22, and the left boundary of the exposure area on the right is the boundary R21. The area between the boundary R21 and the boundary R22 is the two-time exposure area R2. The case where the first exposure is performed on the exposure area on the left and the second exposure is performed on the exposure area on the right is taken as an example.

As shown in FIG. 19A to FIG. 19C, the two-time stitch exposure process includes the following steps.

Step 1): as shown in FIG. 19A, a target thin film TF is formed on a base substrate.

Step 2): forming a photoresist film on the target film TF.

Step 3): performing a first exposure process on the photoresist film to form an exposed photoresist film as shown in FIG. 19A, and the exposed photoresist film includes a pattern P11, a pattern P21 and a pattern P31.

Step 4): performing a second exposure process on the photoresist film to form an exposed photoresist film as shown in FIG. 19B, the exposed photoresist film including a pattern P12, a pattern P22 and a pattern P32.

Step 5): checking whether a first pattern PA and a second pattern PB in the pattern P12 meet the requirements, if not, removing the photoresist film and preparing a photoresist film again, if yes, proceeding to the next step.

Step 6): developing the exposed photoresist film to obtain a photoresist pattern, in which the pattern P12, the pattern P22 and the pattern P32 in the photoresist pattern are reserved, and the rest are removed.

Step 7): etching the target thin film TF using the photoresist pattern shown in FIG. 19B as a mask to form the stitch mark SM1, the gate line GL and the gate electrode GT2 shown in FIG. 19C.

FIG. 19A to FIG. 19C are illustrated by taking the formation of the stitch mark SM1 as an example. The formation process of other stitch marks is also a similar step to the stitch mark SM1, which is not repeated here.

FIG. 18, FIG. 19A to FIG. 19C are illustrated by taking the case where the alignment mark MK (stitch mark SM) further includes a third pattern P3 as an example. For example, the third pattern P3 includes a character or a word. For example, the third pattern P3 includes an English letter. For example, in the embodiment of the present disclosure, the third pattern includes a letter A, a letter S, a letter B, or a letter G. For example, for the stitch mark SM, the case that the third pattern is the letter A indicates that the alignment mark MK (stitch mark SM) refers to the stitch mark of the semiconductor layer SC. For example, the case that the third pattern is the letter S indicates that the alignment mark MK (stitch mark SM) refers to the stitch mark of the source-drain layer LY2. For example, the case that the third pattern is the letter B indicates that the alignment mark MK (stitch mark SM) refers to the stitch mark of the bias voltage line layer LYc. For example, the case that the third pattern is the letter G indicates that the alignment mark MK (stitch mark SM) refers to the stitch mark of the gate layer LY1. Setting the third pattern P3 can better identify the alignment mark MK. In other embodiments, the alignment mark MK (stitch mark SM) may not include the third pattern P3. For example, as shown in FIG. 18, FIG. 19A to FIG. 19C, the third pattern P3 is located on a side of the first pattern P1 and/or the second pattern P2.

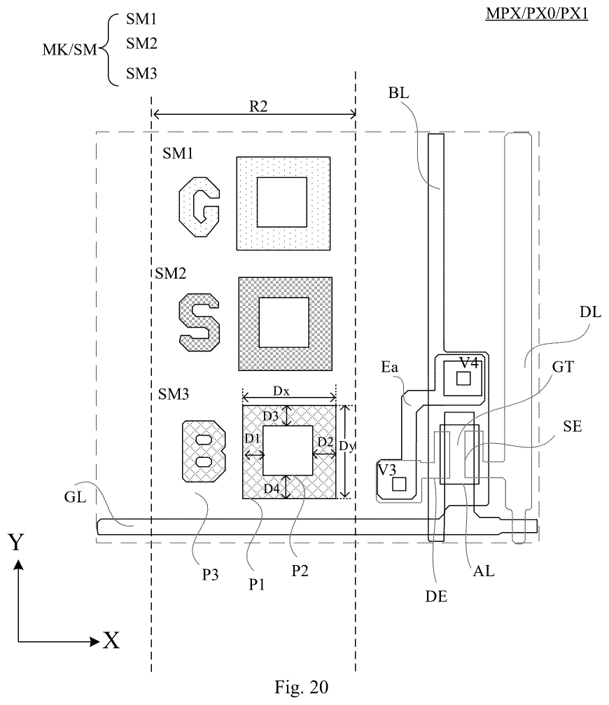

FIG. 20 is a layout diagram of a normally white pixel with stitch marks in a detection substrate provided by an embodiment of the present disclosure. As shown in FIG. 20, the stitch mark SM is arranged in the normally white pixel PX1. The stitch mark SM shown in FIG. 20 can be referred to the stitch mark SM shown in FIG. 18.

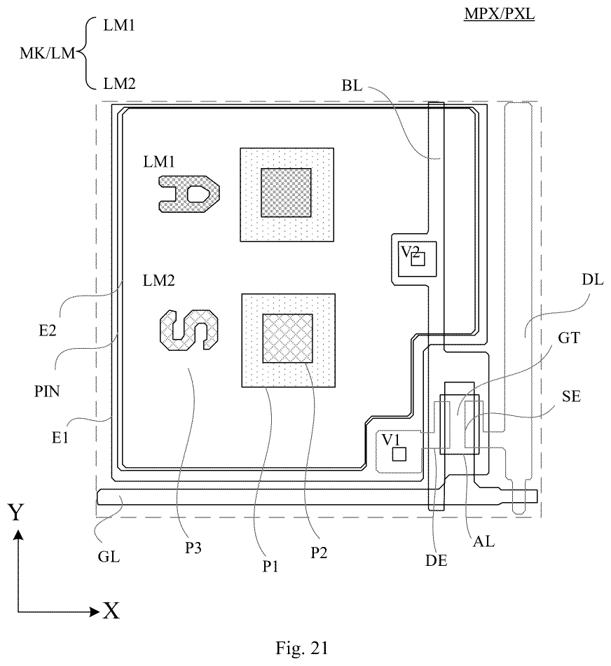

FIG. 21 is a layout diagram of a photosensitive pixel with overlay marks in a detection substrate provided by an embodiment of the present disclosure. As shown in FIG. 21, the overlay mark LM is arranged in the photosensitive pixel PXL.

As shown in FIG. 21, on the basis of a common photosensitive pixel PXL, the overlay marks LM is added to form the marking pixel MPX. As shown in FIG. 21, the first pattern P1 of the overlay mark LM1 is located in the gate layer LY1, the second pattern P2 of the overlay mark LM1 is located in the semiconductor layer SC, and the third pattern P3 of the overlay mark LM1 is located in the semiconductor layer SC, as shown in FIG. 21, the first pattern P1 of the overlay mark LM2 is located in the gate layer LY1, the second pattern P2 of the overlay mark LM2 is located in the source-drain layer LY2, and the third pattern P3 of the overlay mark LM2 is located in the source-drain layer LY2. Therefore, the alignment control of the gate layer LY1—semiconductor layer SC, and the gate layer LY1—source-drain layer LY2 can be realized in the pixel setting area, these three layers have great influence on the characteristics of the transistor, directly relating to the gray uniformity of the image quality and various defects caused by alignment deviation.

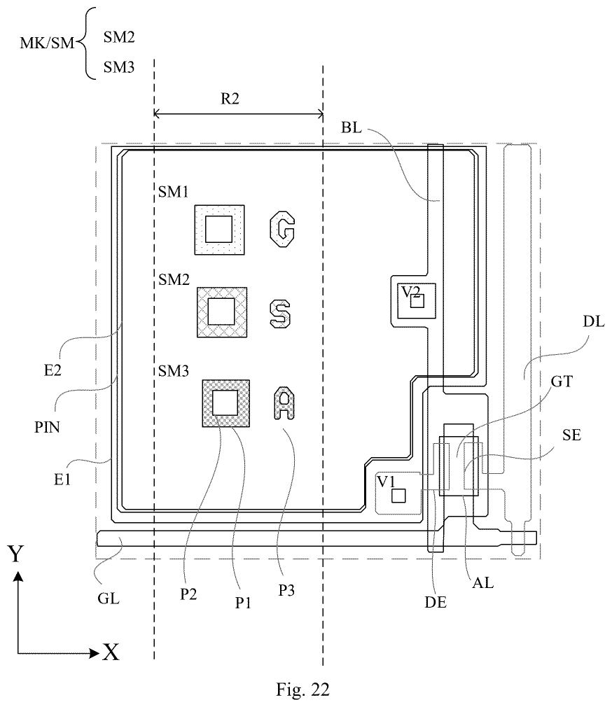

FIG. 22 is a layout diagram of a photosensitive pixel with stitch marks in a detection substrate provided by an embodiment of the present disclosure. As shown in FIG. 22, the stitch mark SM is arranged in the photosensitive pixel PXL.

As shown in FIG. 22, on the basis of a common photosensitive pixel PXL, the stitch mark SM is added, which can monitor the stitch accuracy of the gate layer LY1, the semiconductor layer SC and the source-drain layer LY2 of the stitching unit in the pixel setting area. Because these three layers are the constituent layers of the transistors, thus have great influence on the image quality, and in practical products, improving the stitch accuracy of these three layers can improve the uniformity of the image quality. Setting the stitch mark SM in the photosensitive pixel PXL is beneficial to the stitching alignment, because the stitch mark SM is located under the photoelectric sensing device S0, that is, the stitch mark SM is located between the photoelectric sensing device S0 and the base substrate, the stitch mark SM has little influence on the photosensitive effect of the photosensitive pixel PXL provided with the stitch mark SM. This design can be applied to products that do not need marking pixel. That is, only photosensitive pixels PXL are provided in the detection substrate, and non-photosensitive pixels (normally white pixels and normally black pixels) are not provided, the non-photosensitive pixels may also be called bad pixels. However, the case that the stitch mark SM is arranged in the non-photosensitive pixel (the marking pixel, the normally white pixel or the normally black pixel) can fundamentally avoid the stitch mark SM from affecting the photosensitive effect of the detection substrate.

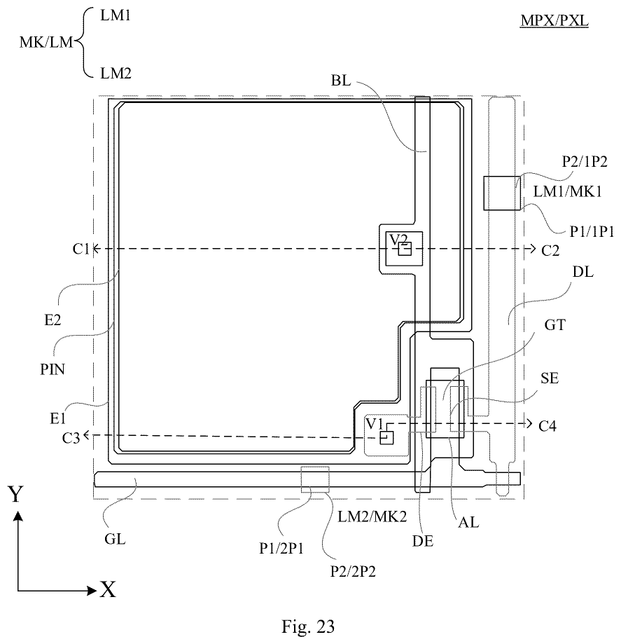

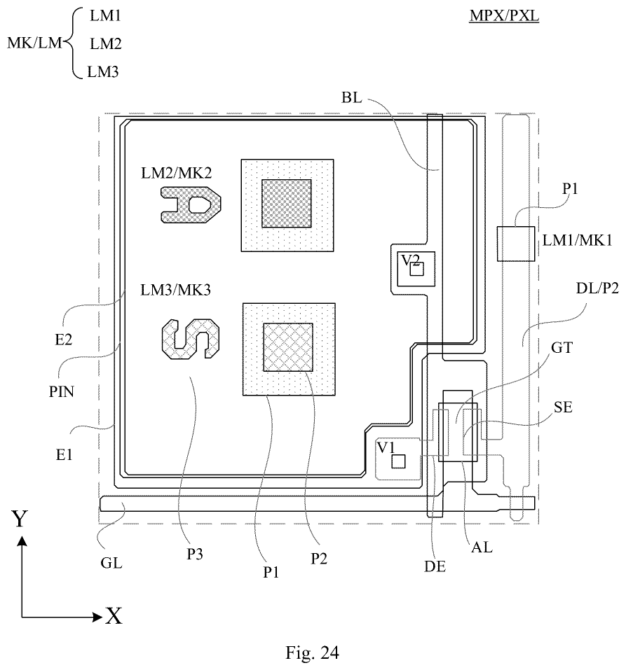

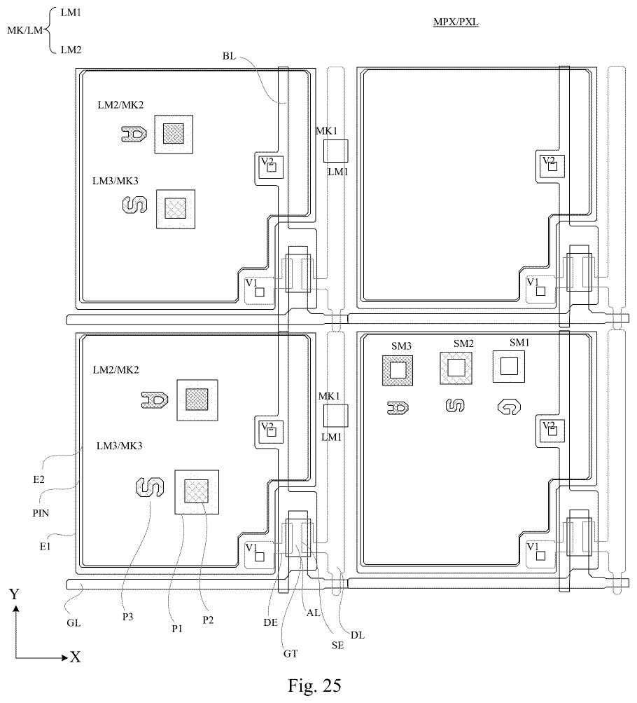

FIG. 23 is a layout diagram of a photosensitive pixel with overlay marks in a detection substrate provided by an embodiment of the present disclosure. FIG. 24 is a layout diagram of a photosensitive pixel with overlay marks in a detection substrate provided by an embodiment of the present disclosure. FIG. 25 is a layout diagram of a photosensitive pixel with overlay marks in a detection substrate provided by an embodiment of the present disclosure.

As shown in FIG. 23 to FIG. 25, the overlay mark LM is arranged in the photosensitive pixel PXL.

FIG. 23 to FIG. 25 show the case that the gate line GL or the data line DL serves as the first pattern P1 or the second pattern P2 of the overlay mark LM.

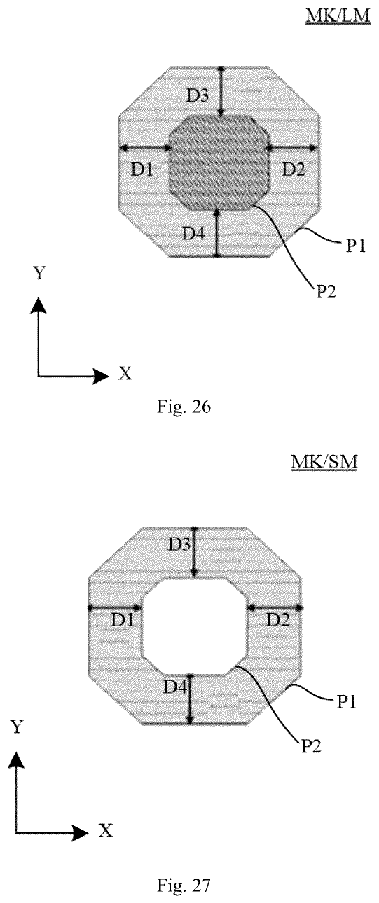

FIG. 26 is a plan view of another overlay mark in a detection substrate provided by an embodiment of the present disclosure. As shown in FIG. 26, the alignment mark MK is an overlay mark LM, the first pattern P1 is octagonal, and the second pattern P2 is octagonal.

FIG. 27 is a plan view of another stitch mark in a detection substrate provided by an embodiment of the present disclosure. As shown in FIG. 27, the alignment mark MK is a stitch mark SM, the first pattern P1 is octagonal, and the second pattern P2 is octagonal.

In an embodiment of the present disclosure, the first pattern P1 of the alignment mark MK may be rectangular, octagonal or circular, and the second pattern P2 of the alignment mark MK may be rectangular, octagonal or circular. The shapes of the first pattern P1 and the second pattern P2 may be determined as required.

FIG. 5, FIG. 8 and FIG. 16 respectively show layout diagrams of the photosensitive pixel PXL, the normally black pixel PX2 and the normally white pixel PX1 in the detection substrate.

As shown in FIG. 5, FIG. 8 and FIG. 16, the detection substrate includes a gate layer LY1, a gate insulation layer GI, a semiconductor layer SC, a source-drain layer LY2, a first passivation layer PVX1, a first electrode layer LYa, a photoelectric sensing layer LY0, a second electrode layer LYb, a planarization layer PLN, a second passivation layer PVX2, a bias voltage line layer LYc and a third passivation layer PVX3.

As shown in FIG. 6, FIG. 7, and FIG. 10 to FIG. 13, in the detection substrate, a gate layer LY1 is arranged on the base substrate, a gate insulation layer GI is arranged on the gate layer LY1, a semiconductor layer SC is arranged on the gate insulation layer GI, a source-drain layer LY2 is arranged on the semiconductor layer SC, a first passivation layer PVX1 is arranged on the source-drain layer LY2, a first electrode layer LYa is arranged on the first passivation layer PVX1, a photoelectric sensing layer LY0 is arranged on the first electrode layer LYa, a second electrode layer LYb is arranged on the photoelectric sensing layer LY0, a planarization layer PLN and a second passivation layer PVX2 are arranged on the second electrode layer LYb, a bias voltage line layer LYc is arranged on the second passivation layer PVX2, and a third passivation layer PVX3 is arranged on the bias voltage line layer LYc.

Each film layer is formed layer by layer through the steps such as film formation, exposure, development, etching and so on. The subsequent conductive layer will not cover the prior layer, that is, it will not affect the recognition of the pattern of the alignment mark.

For example, the base substrate BS may be a rigid substrate, and the material of the rigid substrate includes one selected from a group consisting of glass, quartz and metal. The base substrate BS may also be a flexible substrate, and the material of the flexible substrate includes one of polymers such as polyimide (PI), polyethylene terephthalate (PET), polyethylene naphthalate two formic acid glycol ester (PEN) and polycarbonate (PC) and so on.

For example, the gate insulation layer GI, the first passivation layer PVX1, the second passivation layer PVX2, and the third passivation layer PVX3 are all insulation layers and may be made of inorganic insulating material. For example, the inorganic insulating material includes at least one selected from a group consisting of silicon oxide, silicon nitride and silicon oxynitride.

For example, the planarization layer PLN is an insulation layer and may be made of an organic insulating material. For example, the organic insulating material includes resin, but it is not limited thereto.

As shown in FIG. 5 to FIG. 13, the active layer SC is located on the side of the gate layer LY1 away from the base substrate BS, and the source-drain layer LY2 is located on the side of the active layer SC away from the base substrate BS.

In the embodiment of the present disclosure, the case that a layer B is located on the side of a layer A away from the base substrate BS refers to that the layer B is formed after the layer A, that is, the layer A is formed before the layer B. For example, the case that a layer B is located on the side of a layer A away from the base substrate BS may also refers to that the layer A is closer to the base substrate BS than the layer B.

As shown in FIG. 5, FIG. 8 and FIG. 16, the gate layer LY1 includes a gate line GL and a gate electrode GT, and the gate line GL and the gate electrode GT are of an integral structure. For example, the material of the gate layer LY1 includes metal, but it is not limited to this case.

As shown in FIG. 5, FIG. 8, and FIG. 16, the source-drain layer LY2 includes a data line DL, a source electrode SE, and a drain electrode DE. For example, the material of the source-drain layer LY2 includes metal, but is not limited to this case. For example, the material of the source-drain layer LY2 includes at least one of titanium (Ti) and aluminum (Al).

As shown in FIG. 5, the semiconductor layer SC includes the active layer AL.

As shown in FIG. 5, the first electrode layer LYa includes a first electrode E1. For example, the material of the first electrode layer LYa includes metal. For example, the metal includes at least one selected from a group consisting of molybdenum, aluminum and copper, but it is not limited thereto.

As shown in FIG. 5, the photoelectric sensing layer LY0 includes a photoelectric sensing structure PIN. For example, the photoelectric sensing structure PIN includes an n-type semiconductor layer, an intrinsic semiconductor layer, and a p-type semiconductor layer. For example, the photoelectric sensing structure PIN is a PIN junction. For example, the first electrode E1 is connected to the N-type semiconductor layer, but it is not limited to this case.

As shown in FIG. 5, the second electrode layer LYb includes a second electrode E2. For example, the material of the second electrode layer LYb includes a transparent conductive material. For example, the transparent conductive material includes a transparent conductive metal oxide. For example, the transparent conductive metal oxide includes indium tin oxide (ITO), but it is not limited to this case.

As shown in FIG. 5, the bias voltage line layer LYc includes a bias voltage line BL. The bias voltage line BL is configured to provide a bias voltage to the photosensitive pixel PXL. As shown in FIG. 5 and FIG. 6, the bias voltage line BL is connected to the second electrode E2 through a via hole V2. For example, the bias voltage line layer LYc adopts a conductive material, for example, the conductive material includes metal, but is not limited to this case. For example, the bias voltage line layer LYc adopts at least one selected from a group consisting of molybdenum, aluminum, copper and titanium.

As shown in FIG. 5, the photosensitive pixel PXL includes a transistor T0. The transistor T0 includes an active lay AL, a gate electrode GT, a source electrode SE, and a drain electrode SE.

As shown in FIG. 5, the photosensitive pixel PXL includes a photoelectric sensing device S0. The photoelectric sensing device S0 includes the first electrode E1, the photoelectric sensing structure PIN, and the second electrode E2. As shown in FIG. 5 and FIG. 7, the first electrode E1 is connected to the drain electrode SE through a via hole V1.

As shown in FIG. 8, the semiconductor layer SC includes an active layer AL2. The source-drain layer LY2 includes a source electrode SE2 and a drain electrode DE2. The gate layer LY1 includes a gate electrode GT2. As shown in FIG. 8, the transistor T2 includes the active layer AL2, the gate electrode GT2, the source electrode SE2, and the drain electrode SE2.

As shown in FIG. 8, the bias voltage line layer LYc includes a bias voltage line BL2. The bias voltage line BL2 is not connected to the transistor T2.

The detection substrate shown in FIG. 8 is not provided with the photoelectric sensing device. FIG. 8 shows a normally black pixel PX2.

As shown in FIG. 16, the semiconductor layer SC includes an active layer AL1. The source-drain layer LY2 includes a source electrode SE1 and a drain electrode DE1. The gate layer LY1 includes a gate electrode GT1. As shown in FIG. 16, the transistor T1 includes the active layer AL1, the gate electrode GT1, the source electrode SE1, and the drain electrode DE1.

As shown in FIG. 16, the bias voltage line layer LYc includes a bias voltage line BL1. The bias voltage line BL1 is also configured to provide a bias voltage to the normally white pixel PX1.

As shown in FIG. 16, the bias voltage line BL1 is connected to the drain electrode DE1 through a connection electrode Ea. The connection electrode Ea may be in the same layer as the first electrode E1 or the second electrode E2. As shown in FIG. 16, one end of the connection electrode Ea is connected to the drain electrode DE1 through a via hole V3, and the other end of the connection electrode Ea is connected to the bias voltage line BL1 through a via hole V4.

The detection substrate shown in FIG. 16 is not provided with the photoelectric sensing device. FIG. 16 shows a normally white pixel PX1.

As shown in FIG. 16, the bias voltage is transmitted to the drain electrode DE1 through the connection electrode Ea, and after the transistor T1 is turned on, the bias voltage is read to obtain the marking pixel that is normally bright. The normally white pixel PX1 shown in FIG. 16 is not provided with the photoelectric sensing device S0.

As shown in FIG. 16, by monitoring the size of the distances between the respective boundaries of the first pattern and the second pattern at the top, the bottom, the left and the right, the alignment deviation between the two layers can be obtained, and the alignment deviation between the two layers can meet the design requirements through parameter compensation.

For example, the above-mentioned bias voltage is a common voltage, such as a ground voltage or other types of common voltages. The bias voltage line BL is connected to the photosensitive pixel PXL. The bias voltage line BL is also connected to the normally white pixel PX1.

In the embodiment of the present disclosure, if a column of pixel units includes at least two selected from a group consisting of the photosensitive pixel PXL, the normally black pixel PX2 and the normally white pixel PX1, the two pixel units share the same one bias voltage line. That is, the bias voltage line BL, the bias voltage line BL1, and the bias voltage line BL2 may be the same one bias voltage line and may be of an integral structure.

In the detection substrate provided by the embodiment of the present disclosure, at least one alignment mark MK may be arranged in at least one selected from the group consisting of the photosensitive pixel PXL, the normally black pixel PX2 and the normally white pixel PX1.

For example, as shown in FIG. 9 to FIG. 13, FIG. 15B, FIG. 17, FIG. 18 and FIG. 20 to FIG. 27, in the detection substrate, the alignment mark MK includes a first pattern P1 and a second pattern P2, and the orthographic projection of the second pattern P2 on the base substrate BS overlaps with the orthographic projection of the first pattern P1 on the base substrate BS.

In the detection substrate provided by the embodiment of the present disclosure, the second pattern P2 overlaps with the first pattern P1, which is beneficial to monitoring the alignment accuracy.

For example, as shown in FIG. 18, FIG. 20, FIG. 22, FIG. 25 and FIG. 27, in the detection substrate, the alignment mark MK includes a stitch mark SM, the first pattern P1 of the stitch mark SM is an alignment material layer, and the second pattern P2 of the stitch mark SM is a hollow area. That is, the stitch mark SM is a component in a single layer.

For example, as shown in FIG. 9 to FIG. 13, FIG. 15B, FIG. 17, FIG. 21, FIG. 23 and FIG. 25, in the detection substrate, the alignment mark MK includes an overlay mark LM, the first pattern P1 of the overlay mark LM is a first material layer, and the second pattern P2 of the overlay mark LM is a second material layer, and the materials of the first material layer and the second material layer are different. That is, the overlay mark LM includes two overlapping parts respectively located in two different layers.

For example, as shown in FIG. 9 to FIG. 13, FIG. 15B, FIG. 17, FIG. 21, FIG. 23, and FIG. 25, in the detection substrate, a plurality of overlay marks LM are provided in the same one marking pixel MPX, the materials of the first patterns P1 of the plurality of overlay marks LM are the same, and the materials of the second patterns P2 of at least two overlay marks LM among the plurality of overlay marks LM are different. The overlay mark LM includes a bottom pattern and a top pattern, in the embodiment of the present disclosure, the first pattern P1 is the bottom pattern and the second pattern P2 is the top pattern, the bottom patterns of a plurality of overlay marks LM may be arranged in the same layer, such as the gate layer LY1, and the top pattern may be arranged in other layers different from the bottom pattern as required, so as to facilitate alignment monitoring in the manufacturing process of the detection substrate.

For example, as shown in FIG. 9 to FIG. 13, FIG. 15B, FIG. 17, FIG. 21, FIG. 23, and FIG. 25, in the detection substrate, a plurality of overlay marks LM are spaced apart from each other, and are sequentially arranged in one direction or arranged in an array in two directions. Of course, a plurality of overlay marks LM may also arranged in other manners. As shown in FIG. 9 and FIG. 17, a plurality of overlay marks LM are arranged in an array. FIG. 9 and FIG. 17 show nine overlay marks LM arranged in three rows and three columns. The number of the overlay marks LM is not limited to the case shown in the figures. In FIG. 9 and FIG. 17, the overlay marks LM are arranged in the marking pixel, however, the embodiments of the present disclosure are not limited to this case, and the overlay mark LM may also be arranged in the photosensitive pixel. FIG. 21 shows two overlay marks LM: the overlay mark LM1 and the overlay mark LM2. FIG. 23 shows that the overlay mark LM is arranged in the photosensitive pixel PXL. FIG. 23 shows an overlay mark LM1 and an overlay mark LM2. FIG. 24 shows three overlay marks LM: the overlay mark LM1, the overlay mark LM2, and the overlay mark LM3. FIG. 25 shows three overlay marks LM: the overlay mark LM1, the overlay mark LM2, and the overlay mark LM3, and shows three stitch marks: the stitch mark SM1, the stitch mark SM2, and the stitch mark SM3.

For example, as shown in FIG. 9 to FIG. 13 and FIG. 17, in the detection substrate, the detection substrate includes a gate layer LY1, a semiconductor layer SC, and a source-drain layer LY2, and a plurality of overlay marks LM include an overlay mark LM1 and an overlay mark LM2. The first pattern P1 of the overlay mark LM1 is located in the gate layer LY1, and is in the same layer as the gate electrode GT and the gate line GL. The second pattern P2 of the overlay mark LM1 is located in the semiconductor layer SC and is in the same layer as the active layer AL. The first pattern P1 of the overlay mark LM2 is in the gate layer LY1, and is in the same layer as the gate electrode GT and the gate line GL. The second pattern P2 of the overlay mark LM2 is located in the source-drain layer LY2, and is in the same layer as the source electrode SE, the drain electrode DE, and the data line DL.

For example, as shown in FIG. 21, FIG. 23 and FIG. 25, in the detection substrate, a plurality of overlay marks LM are located in the same one photosensitive pixel PXL. In order not to affect the function of the photosensitive pixel PXL, the number of overlay marks LM arranged in the same one photosensitive pixel PXL may be less than or equal to three. FIG. 21 and FIG. 25 take setting three overlay marks LM in the same one photosensitive pixel PXL as an example. FIG. 23 takes setting two overlay marks LM in the same one photosensitive pixel PXL as an example. As shown in FIG. 21 and FIG. 25, the first pattern P1 of the overlay mark LM1 may be located at the gate layer LY1, and the second pattern P2 of the overlay mark LM1 may be located at the semiconductor layer SC. As shown in FIG. 21 and FIG. 25, the first pattern P1 of the overlay mark LM2 may be located in the gate layer LY1, and the second pattern P2 of the overlay mark LM1 may be located in the source-drain layer LY2. As shown in FIG. 23 and FIG. 25, the data line DL serves as the second pattern P2 (the second pattern 1P2) of the overlay mark LM1, and the first pattern P1 (the first pattern 1P1) of the overlay mark LM1 is located in the gate layer LY1.

As shown in FIG. 23, two overlay marks LM, namely the overlay mark LM1 and the overlay mark LM2, are located in the same one photosensitive pixel PXL. As shown in FIG. 23, the gate line GL serves as the first pattern P1 (the first pattern 2P1) of the overlay mark LM2, and the second pattern P2 (the second pattern 2P2) of the overlay mark LM2 is located in the source-drain layer LY2. As shown in FIG. 23, the data line DL serves as the second pattern P2 (the second pattern 1P2) of the overlay mark LM1, and the first pattern P1 (the first pattern 1P1) of the overlay mark LM1 is located in the gate layer LY1. FIG. 23 shows the case that the overlay mark LM1 and the overlay mark LM2 are arranged in the same one photosensitive pixel PXL. In other embodiments, the overlay mark LM1 or the overlay mark LM2 may be arranged in the same one photosensitive pixel PXL.

For example, as shown in FIG. 5 and FIG. 23, in the detection substrate, the detection substrate further includes a gate line GL and a data line DL, the photosensitive pixel PXL includes a transistor T0, the gate line GL is connected to the gate electrode GT of the transistor T0, and the data line DL is connected to the source electrode SE of the transistor TO.

For example, as shown in FIG. 23, in the detection substrate, the direction X is parallel with the extension direction of the gate line GL, and for the overlay mark LM1, the first pattern P1 (the first pattern 1P1) is in the same layer as the gate line GL, and the data line DL serves as the second pattern P2 (the second pattern 1P2).

As shown in FIG. 23, the direction Y is parallel with the extension direction of the data line GL, the second pattern P2 (the second pattern 2P2) is in the same layer as the data line DL, and the gate line GL serves as the first pattern P1 (the first pattern 2P1).

In the embodiment of the present disclosure, the direction X is parallel with the base substrate, the direction Y is parallel with the base substrate, and the direction X intersects with the direction Y. For example, the direction X is perpendicular to the direction Y.

For example, the direction X and the direction Y are parallel with the surface of the base substrate for manufacturing various components.

For example, as shown in FIG. 9 to FIG. 11, in the detection substrate, the detection substrate further includes a first passivation layer PVX1, the first passivation layer PVX1 is located on the side of the source-drain layer LY2 away from the base substrate BS, and the plurality of overlay marks LM further includes an overlay mark LM3. The first pattern P1 of the overlay mark LM3 is located in the gate layer LY1, and is in the same layer as the gate electrode GE and the gate line GL. The second pattern P2 of the overlay mark LM3 is a via hole HPVX1 in the first passivation layer PVX1.

For example, as shown in FIG. 9 to FIG. 13, in the detection substrate, the detection substrate further includes a first passivation layer PVX1, a first electrode layer LYa, a photoelectric sensing layer L0, a planarization layer PLN, a second passivation layer PVX2, a bias voltage line layer LYc, and a third passivation layer PVX3 which are sequentially arranged. A plurality of overlay marks LM are located in the same one marking pixel MPX, and further includes an overlay mark LM3, an overlay mark LM4, an overlay mark LM5, an overlay mark LM6, an overlay mark LM7, an overlay mark LM8, and an overlay mark LM9, and furthermore, the first patterns P1 of the overlay mark LM3, the overlay mark LM4, the overlay mark LM5, the overlay mark LM6, the overlay mark LM7, the overlay mark LM8, and the overlay mark LM9 are all located in the same layer, that is, in the same layer as the gate electrode GE and the gate line GL, and the second pattern P2 of the overlay mark LM3 is the via hole HPVX1 in the first passivation layer PVX1, and the second pattern P2 of the overlay mark LM4 is located in the first electrode layer LYa, that is, is located in the same layer as the first electrode E1. The second pattern P2 of the overlay marks LM5 is located in the photoelectric sensing layer L0, that is, in the same layer as the photoelectric sensing structure PIN, and the second pattern P2 of the overlay marks LM6 is a via hole HPLN in the planarization layer PLN. The second pattern P2 of the overlay mark LM7 is a via hole HPVX2 in the second passivation layer PVX2, the second pattern P2 of the overlay mark LM8 is located in the second electrode layer LYb, that is, in the same layer as the second electrode E2, and the second pattern P2 of the overlay mark LM9 is located in the bias voltage line layer LYc, that is, in the same layer as the bias voltage line BL.

As shown in FIG. 9 to FIG. 13, the overlay mark LM1 has a first pattern P1 (the first pattern 1P1) and a second pattern P2 (the second pattern 1P2).

As shown in FIG. 9 to FIG. 13, the overlay mark LM2 has a first pattern P1 (the first pattern 2P1) and a second pattern P2 (the second pattern 2P2).

As shown in FIG. 9 to FIG. 13, the overlay mark LM3 has a first pattern P1 (the first pattern 3P1) and a second pattern P2 (the second pattern 3P2).

As shown in FIG. 9 to FIG. 13, the overlay mark LM4 has a first pattern P1 (the first pattern 4P1) and a second pattern P2 (the second pattern 4P2).

As shown in FIG. 9 to FIG. 13, the overlay mark LM5 has a first pattern P1 (the first pattern 5P1) and a second pattern P2 (the second pattern 5P2).

As shown in FIG. 9 to FIG. 13, the overlay mark LM6 has a first pattern P1 (the first pattern 6P1) and a second pattern P2 (the second pattern 6P2).

As shown in FIG. 9 to FIG. 13, the overlay mark LM7 has a first pattern P1 (the first pattern 7P1) and a second pattern P2 (the second pattern 7P2).

As shown in FIG. 9 to FIG. 13, the overlay mark LM8 has a first pattern P1 (the first pattern 8P1) and a second pattern P2 (the second pattern 8P2).

As shown in FIG. 9 to FIG. 13, the overlay mark LM9 has a first pattern P1 (the first pattern 9P1) and a second pattern P2 (the second pattern 9P2).

For example, as shown in FIG. 18 and FIG. 20, in the detection substrate, the stitch mark SM includes a first stitch mark SM1, a second stitch mark SM2 and a third stitch mark SM3. The first stitch mark SM1 is located at the gate layer LY1, that is, in the same layer as the gate electrode GE and the gate line GL. The second stitch mark SM2 is located in the source-drain layer LY2, that is, in the same layer as the source electrode SE, the drain electrode DE and the data line DL. The third stitch mark SM3 is located in the bias voltage line layer LYc, that is, in the same layer as the bias voltage line BL. In the normally white pixel PX1, the gate layer LY1, the source-drain layer LY2 and the bias voltage line layer LYc are important layer structures, thus stitch marks are arranged in these three layers to facilitate stitching alignment.

For example, as shown in FIG. 22, in the detection substrate, the stitch mark SM includes a first stitch mark SM1, a second stitch mark SM2 and a third stitch mark SM3. The first stitch mark SM1 is located in the gate layer LY1, that is, in the same layer as the gate electrode GE and the gate line GL. The second stitch mark SM2 is located in the source-drain layer LY2, that is, in the same layer as the source electrode SE, the drain electrode DE and the data line DL. The third stitch mark SM3 is located in the semiconductor layer SC, that is, in the same layer as the active layer AL. Because the gate layer LY1, the semiconductor layer SC and the source-drain layer LY2 are crucial to the formation of the transistor T0, the stitch mark SM may include the above-mentioned three stitch marks SM to form the transistor T0 with high reliability. The three stitch marks SM shown in FIG. 18 are located in the same one normally black pixel PX2, and in other embodiments, the same one normally black pixel PX2 may be provided with one, two or more than three stitch marks SM.

For example, as shown in FIG. 2 and FIG. 3, in the detection substrate, the marking pixel MPX includes the first marking pixel MPX1, the stitch mark SM is located in the first marking pixel MPX1, the marking pixel MPX includes the second marking pixel MPX2, and the overlay mark LM is located in the second marking pixel MPX2. In the detection substrate shown in FIG. 2, the overlay mark LM or the stitch mark SM may be arranged in the second marking pixel MPX2. That is, in one second marking pixel MPX2, at least one of the overlay mark LM and the stitch mark SM may be provided.

For example, as shown in FIG. 2, in the detection substrate, the first marking pixel MPX1 and the second marking pixel MPX2 are adjacent to each other, or as shown in FIG. 3, the first marking pixel MPX1 and the second marking pixel MPX2 are spaced apart from each other, and at least one of a plurality of non-marking pixels (the photosensitive pixels PXL) is provided between the first marking pixel MPX1 and the second marking pixel MPX2.

For example, the remaining pixel units except the marking pixel MPX are called non-marking pixels. That is, the plurality of pixel units PXU include a marking pixel MPX and an non-marking pixel. For example, the non-marking pixel includes the photosensitive pixel PXL.

As shown in FIG. 1 to FIG. 4, the marking pixel MPX or the photosensitive pixel PXL provided with the alignment mark MK is located at the edge of the exposure area. In one exposure area, the larger the area surrounded by pixel units containing alignment marks MK, the better.

For example, as shown in FIG. 9, FIG. 17, FIG. 18, FIG. 20, FIG. 21, FIG. 22, FIG. 24, and FIG. 25, in the detection substrate, the first pattern P1 and the second pattern P2 have a first boundary distance D1 and a second boundary distance D2 in the direction X, the ratio of the first boundary distance D1 to the larger one of the size of the first pattern P1 in the first direction X and the size of the second pattern P2 in the first direction X is less than or equal to ⅓, and the ratio of the second boundary distance D2 to the larger one of the size of the first pattern P1 in the first direction X and the size of the second pattern P2 in the first direction X is less than or equal to ⅓. FIG. 17 and FIG. 20 show the size Dx of the first pattern P1 in the direction X.

According to the detection substrate provided by the embodiment of the present disclosure, by defining the upper limit of the range of the two boundary distances between the first pattern P1 and the second pattern P2 in the lateral direction, the lateral alignment can be more accurate.

For example, in the detection substrate, the ratio of the first boundary distance D1 to the larger one of the size of the first pattern P1 in the first direction X and the size of the second pattern P2 in the first direction X is larger than or equal to ¼, and the ratio of the second boundary distance D2 to the larger one of the size of the first pattern P1 in the first direction X and the size of the second pattern P2 in the first direction X is larger than or equal to ¼.

According to the detection substrate provided by the embodiment of the present disclosure, by defining the lower limit of the range of the two boundary distances between the first pattern P1 and the second pattern P2 in the lateral direction, the lateral alignment can be more accurate.

In some embodiments, the ratio of the first boundary distance D1 to the larger one of the size of the first pattern P1 in the first direction X and the size of the second pattern P2 in the first direction X is larger than or equal to ¼ and less than or equal to ⅓, and the ratio of the second boundary distance D2 to the larger one of the size of the first pattern P1 in the first direction X and the size of the second pattern P2 in the first direction X is larger than or equal to ¼ and less than or equal to ⅓.

According to the detection substrate provided by the embodiment of the present disclosure, by defining the upper limit and the lower limit of the range of the two boundary distances between the first pattern P1 and the second pattern P2 in the lateral direction, the lateral alignment can be more accurate.

For example, as shown in FIG. 23 and FIG. 25, in the detection substrate, the alignment mark MK includes an alignment mark MK1 (the overlay mark LM1) and an alignment mark MK2 (the overlay mark LM2), the data line DL extends in the direction Y, and the direction X is perpendicular to the extension direction of the data line DL, the gate line GL extends in the direction X, the gate line GL serves as the first pattern P1 of the alignment mark MK2 (the overlay mark LM2), and the second pattern P2 of the alignment mark MK2 is in the same layer as the data line DL. The first pattern P1 of the alignment mark MK1 (the overlay mark LM1) is in the same layer as the gate line GL, that is, in the gate layer LY1, and the data line DL serves as the second pattern P2 of the alignment mark MK1 (the overlay mark LM1).

For example, as shown in FIG. 24 and FIG. 25, in the detection substrate, the alignment mark MK includes the alignment mark MK1 (the overlay mark LM1), the first pattern P1 of the alignment mark MK1 (the overlay mark LM1) is in the same layer as the gate line GL, that is, located in the gate layer LY1, and the data line DL serves as the second pattern P2 of the alignment mark MK1 (the overlay mark LM1).

For example, as shown in FIG. 24 and FIG. 25, in the detection substrate, the alignment mark MK further includes an alignment mark MK2 (the overlay mark LM2), and the orthographic projection of the second pattern P2 of the alignment mark MK2 on the base substrate BS is within the orthographic projection of the first pattern P1 of the alignment mark MK2 on the base substrate BS. For example, as shown in FIG. 24 and FIG. 25, the first pattern P1 of the alignment mark MK2 (the overlay mark LM2) is located in the gate layer LY1, and the second pattern P2 of the alignment mark MK2 (the overlay mark LM2) is located in the semiconductor layer SC.

For example, as shown in FIG. 24 and FIG. 25, in this detection substrate, the alignment mark MK further includes an alignment mark MK3 (the overlay mark LM3), and the orthographic projection of the second pattern P2 of the alignment mark MK3 on the base substrate BS is within the orthographic projection of the first pattern P1 of the alignment mark MK3 on the base substrate BS. For example, as shown in FIG. 24 and FIG. 25, the first pattern P1 of the alignment mark MK3 (the overlay mark LM3) is located in the gate layer LY1, and the second pattern P2 of the alignment mark MK3 (the overlay mark LM3) is located in the source-drain layer LY2. For example, as shown in FIG. 9, FIG. 17 and FIG. 21, in this detection substrate, the orthographic projection of the second pattern P2 on the base substrate BS is within the orthographic projection of the first pattern P1 on the base substrate BS.

For the alignment mark MK2 (the overlay mark LM2) and alignment mark MK3 (the overlay mark LM3) in FIG. 24 and FIG. 25, the orthographic projection of the second pattern P2 on the base substrate BS is within the orthographic projection of the first pattern P1 on the base substrate BS.

For example, as shown in FIG. 9, FIG. 17, FIG. 18, FIG. 20, FIG. 21, FIG. 22, FIG. 24, and FIG. 25, in the detection substrate, the first pattern P1 and the second pattern P2 have a third boundary distance D3 and a fourth boundary distance D4 in the direction Y, the ratio of the third boundary distance D3 to the size of the first pattern P1 in the direction Y is less than or equal to ⅓, and the ratio of the fourth boundary distance D4 to the size of the first pattern P1 in the direction Y is less than or equal to ⅓. FIG. 17 shows the size Dy of the first pattern P1 in the direction Y.

According to the detection substrate provided by the embodiment of the present disclosure, by defining the upper limit of the two boundary distances between the first pattern P1 and the second pattern P2 in the vertical direction, the vertical alignment can be more accurate.

For example, in the detection substrate, the first pattern P1 and the second pattern P2 have a third boundary distance D3 and a fourth boundary distance D4 in the direction Y, the ratio of the third boundary distance D3 to the size of the first pattern P1 in the direction Y is greater than or equal to ¼, and the ratio of the fourth boundary distance D4 to the size of the first pattern P1 in the direction Y is greater than or equal to ¼.

According to the detection substrate provided by the embodiment of the present disclosure, by defining the lower limit of the two boundary distances between the first pattern P1 and the second pattern P2 in the vertical direction, the vertical alignment can be more accurate.

For example, in some embodiments, the ratio of the third boundary distance D3 to the size of the first pattern P1 in the direction Y is greater than or equal to ¼ and less than or equal to ⅓, and the ratio of the fourth boundary distance D4 to the size of the first pattern P1 in the direction Y is greater than or equal to ¼ and less than or equal to ⅓.

According to the detection substrate provided by the embodiment of the present disclosure, by defining the upper limit and the lower limit of the two boundary distances between the first pattern P1 and the second pattern P2 in the vertical direction, the vertical alignment can be more accurate.

For example, as shown in FIG. 9, FIG. 17, FIG. 18, FIG. 20, FIG. 21, FIG. 22, FIG. 24, and FIG. 25, in the detection substrate, at least two alignment marks MK are provided in the same one marking pixel MPX, and the two alignment marks MK are spaced apart from each other. The alignment marks MK are spaced apart from each other, which is beneficial to the determination of the boundary distance of each alignment mark MK.

For example, in the detection substrate, the photosensitive pixel PXL includes a first pixel structure PXS1, and the marking pixel MPX includes a second pixel structure PXS2, and the first pixel structure PXS1 is different from the second pixel structure PXS2.

FIG. 25 shows four photosensitive pixels PXL, the photosensitive pixel in the upper right corner is not a marking pixel MPX, and the other three photosensitive pixels PXL are all marking pixels MPX. The marking pixel MPX in the upper left corner of FIG. 25 has overlay marks: the overlay mark LM1, the overlay mark LM2, and the overlay mark LM3. The marking pixel MPX in the lower left corner of FIG. 25 has overlay marks: overlay mark LM1, overlay mark LM2, and overlay mark LM3. The marking pixel MPX in the lower right corner of FIG. 25 has stitch marks: stitch mark SM1, stitch mark SM2, and stitch mark SM3.

FIG. 25 takes the case where the alignment mark MK (the overlay mark LM) further includes a third pattern P3 as an example. For example, the third pattern P3 includes a character or a word. For example, the third pattern P3 includes an English letter. For example, in the embodiment of the present disclosure, the third pattern includes a letter A, a letter S, a letter B, or a letter G.

For example, as shown in FIG. 25, in the overlay mark LM, the case that the third pattern is the letter A refers to that the second pattern P2 of the alignment mark MK (the overlay mark LM) is located in the semiconductor layer SC. For example, the case that the third pattern is the letter S refers to that the second pattern P2 of the alignment mark MK (the overlay mark LM) is located in the source-drain layer LY2. For example, the third pattern is the letter B refers to that the second pattern P2 of the alignment mark MK (the overlay mark LM) is located in the bias voltage line layer LYc. For example, the case that the third pattern is the letter G refers to that the second pattern P2 of the alignment mark MK (the overlay mark LM) is located in the gate layer LY1. Setting the third pattern P3 can better identify the alignment mark MK. In other embodiments, the alignment mark MK (the overlay mark LM) may not include the third pattern P3. For example, as shown in FIG. 25, the third pattern P3 is located on one side of the first pattern P1 and/or the second pattern P2.

For example, as shown in FIG. 5 to FIG. 7 and FIG. 9 to FIG. 13, in the detection substrate, the first pixel structure PXS1 includes a transistor T0, a photoelectric sensing device S0, and a bias voltage line BL, and the first electrode E1 of the photoelectric sensing device S0 is electrically connected with the transistor T0, and the second electrode E2 of the photoelectric sensing device S0 is electrically connected with the bias voltage line BL.

For example, as shown in FIG. 8 and FIG. 9, the second pixel structure PXS2 includes a transistor T2, or as shown in FIG. 16 and FIG. 17, the second pixel structure PXS2 includes a transistor T1, a connection electrode Ea, and a bias voltage line BL1, the bias voltage line BL1 is electrically connected with the transistor T1 through the connection electrode Ea. In this case, the second pixel structure PXS2 is a pixel structure of a normally white pixel PX1, or, the second pixel structure PXS2 includes a transistor T1, a photoelectric sensing device, and a bias voltage line BL. The first electrode E1 of the photoelectric sensing device is connected with the transistor T1, the second electrode of the photoelectric sensing device is not electrically connected with the bias voltage line BL, and in this case, the second pixel structure PXS2 is a pixel structure of a normally black pixel PX2.

For example, as shown in FIG. 1, it is an example of the arrangement and combination of marking pixels, and it is an example of the smallest pixel array splicing unit (the actual unit size needs to be treated according to the specific situation of each product), each square represents a pixel unit, and the pixel design shown in FIG. 17 or FIG. 20 may be used for the normally white pixel PX1, and the pixel design shown in FIG. 9 or FIG. 18 may be used for the normally black pixel PX2; the pixel unit with the stitch mark (the marking pixel MPX) may adopts the pixel design with the stitch mark as shown in FIG. 18 or FIG. 20, which can not only realize the image positioning function of the marking pixel, but also realize the alignment control in the manufacturing process, killing two birds with one stone, and is a pixel design scheme beneficial to the stable production of products.

For example, as shown in FIG. 2, it is another example of the arrangement and combination of the marking pixels, and it is an example of the smallest pixel array splicing unit (the actual unit size needs to be treated specifically according to the specific situation of each product), each square represents a pixel unit PXU, the marking pixel MPX adopts the design in FIG. 21 or FIG. 22, the marking pixel MPX2 is a pixel unit for monitoring the overlay, and the marking pixel MPX1 is a pixel for monitoring the stitch accuracy, in the products that don't need normally black pixels or normally white pixels, this scheme can be used to control the alignment and stitch accuracy of the patterns.

It should be pointed out that the number and size of the patterns of the alignment marks may be set according to the size of pixels and the requirements of the alignment accuracy; the number of marking pixels may be adjusted as required. In addition to the square shape, the pattern of the alignment mark may also be designed by selecting a pattern with a straight outline and a symmetrical center, such as rectangle and octagon, and the respective boundary distances of the inner pattern and the outer pattern may be the same at the top, the bottom, the left, and the right, as shown in FIG. 26 and FIG. 27.

For example, in the embodiment of the present disclosure, the alignment mark MK is located between the third passivation layer PVX3 and the base substrate BS. For example, as shown in FIG. 9 to FIG. 13, FIG. 17, FIG. 21, FIG. 24 and FIG. 25, the alignment mark MK (the overlay mark LM) is located between the third passivation layer PVX3 and the base substrate BS. For example, as shown in FIG. 9 to FIG. 13, FIG. 18, FIG. 20 and FIG. 22, the alignment mark MK (the stitch mark SM) is located between the third passivation layer PVX3 and the base substrate BS. According to the above descriptions, the stitch mark SM may be located in the gate layer LY1, the source-drain layer LY2, the semiconductor layer SC or the bias voltage line layer LYc, it can be known that the alignment mark MK (the stitch mark SM) is located between the third passivation layer PVX3 and the base substrate BS.

For example, in the case where the stitch mark SM or the overlay mark LM is located in the gate layer LY1, the source-drain layer LY2, or the semiconductor layer SC, the alignment mark MK (including at least one of the stitch mark SM and the overlay mark LM) is located between the first passivation layer PVX1 and the base substrate BS.

It should be noted that the specific layer in which the alignment mark is designed may be determined as required, and is not limited to the case described in the attached drawings. For example, for the embodiments shown in FIG. 9 and FIG. 17, only one or several overlay marks among the overlay marks LM1 to LM9 may be provided. The same is true for the pixel units provided with the stitch mark SM, and one or several among the stitch marks SM may be selected to be provided in one pixel unit.

Embodiments of the present disclosure further provide a detector including any one of the above-mentioned detection substrates. The detector may be a flat panel detector.

Embodiments of the present disclosure further provide an imaging system including any one of the above-mentioned detectors.

In the case where the detector includes an image acquisition area, a plurality of photosensitive pixels generate a charge image according to electrical signals. The detector may also include a coordinate acquisition unit and a data output unit. The coordinate acquisition unit is configured to acquire the coordinate of each positioning pixel and the real-time coordinates of at least some photosensitive pixels used to form the charge image; the data output unit is configured to output the electrical signal of each photosensitive pixel for forming the image, and to output the coordinate of each positioning pixel and the real-time coordinates of at least some photosensitive pixels for positioning the charge image, so as to control the charge image to always be located in the image acquisition area. For example, for the convenience of operation, the positioning point is selected on the charge image, and the position of the detector is adjusted according to the positional relationship between the positioning point and the positioning pixel or the alignment mark, and the detector can move so that the charge image is always located in the image acquisition area.

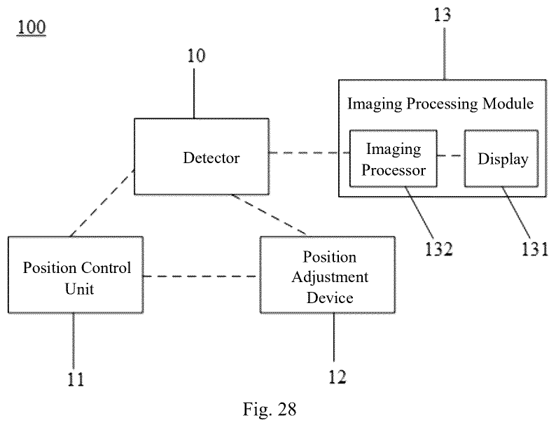

FIG. 28 is a schematic diagram of the imaging system provided by an embodiment of the present disclosure. As shown in FIG. 28, the imaging system 100 includes any one of the detectors 10 provided by the embodiments of the present disclosure, a position control unit 11, a position adjustment device 12 and an imaging processing module 13. The position control unit 11 is configured to receive the coordinate of the positioning pixel and the real-time coordinates of at least some photosensitive pixels in real time from the detector 10, calculate the distance of the at least some photosensitive pixels relative to the positioning pixel by using the received coordinates, and send an instruction according to the calculation result. The at least part of the photosensitive pixels are used for generating a charge image by light sensing, for example, are some selected photosensitive pixels. The position adjustment device 12 is configured to receive an instruction from the position control unit 11 in real time, and under the control of the instruction, the position of the detector 10 is adjusted in real time so that the charge image is always located in the image acquisition area D. The imaging processing module 13 includes a display 131 and an imaging processor 132. The display 131 includes a preset display area; the imaging processor 132 is configured to receive the electrical signals output by the detector 10 and the position information of the charge image after adjusting the position of the detector 10, and generate an image of the object to be imaged in the preset display area by using the electrical signals and the position information of the charge image.

For example, for the purpose of convenient operation, the positioning point is selected on the charge image, and the coordinates of the positioning point and the positional relationship between the positioning point and the positioning pixel or the alignment mark are obtained through the position control unit 11. For example, the position control unit 11 includes a processor, the distance between the positioning point and the positioning pixel or the alignment mark is calculated by the processor, the position of the detector 10 is adjusted according to this distance, and the detector 10 is moved so that the charge image can be always located in the image acquisition area.

For example, the imaging system 100 further includes a light emitter, the light emitter is configured to emit light to an object to be imaged, light passes through the object to be imaged and illuminates the detector 10, and the light passing through the object to be imaged is the above-mentioned incident light.

For example, the light emitter is configured to rotate around the object to be imaged, and emits light to the object to be imaged at a plurality of angles to generate a corresponding charge image in real time at each of the angles respectively. The image processing module generate a three-dimensional image in a preset display area by processing a plurality of charge images generated by emitting the light to the object to be imaged at a plurality of angles.

For example, the imaging system 100 can be used in the field of medical detection, and the light emitter emits X-rays. The imaging system 100 utilizes the X-rays to form an image of a part, such as an organ, of a human body. In this case, the imaging system 100 provided by the embodiment of the present disclosure can form an ideal image of the object to be detected, such as an ideal stereoscopic image, present the morphology of the object to be detected more truly and accurately, obtain more real and accurate image information, improve the accuracy of the detection result, and improve the imaging speed, and conveniently make the formed image always be in the preset area of the display, with simple operation and a good image output effect. Of course, in some embodiments, the light emitted by the light emitter may also be visible light for forming a black-and-white image or a color image. The black-and-white image or color image is, for example, a two-dimensional image or a stereoscopic image. The application scenarios and imaging types of the flat panel detector provided by the embodiments of the present disclosure are not limited to the above situations.

The embodiment of the present disclosure further provides a manufacturing method of a detection substrate which includes: forming a plurality of pixel units PXU in a pixel setting area R0 of a base substrate BS, the plurality of pixel units PXU including a marking pixel MPX, and at least one alignment mark MK is arranged in the marking pixel MPX.

According to the manufacturing method of the detection substrate provided by the embodiment of the present disclosure, the alignment mark MK is arranged in at least one of the plurality of marking pixels MPX, so as to facilitate monitoring the stitch accuracy and/or alignment accuracy in the manufacturing process of the detection substrate and avoid the image quality problem of uneven gray scale in the final product image.

For example, in the manufacturing method of the detection substrate, forming a plurality of pixel units PXU includes forming a plurality of photosensitive pixels PXL and forming a plurality of positioning pixels PX0, at least one marking pixel MPX among the plurality of marking pixels MPX is adjacent to at least one photosensitive pixel PXL among the plurality of photosensitive pixels PXL; the marking pixel MPX includes at least one positioning pixel among the plurality of positioning pixels PX0 and/or at least one photosensitive pixel among the plurality of photosensitive pixels PXL.

For example, in the manufacturing method of the detection substrate, forming the alignment mark MK includes: forming a first pattern P1 and forming a second pattern P2, and the orthographic projection of the second pattern P2 on the base substrate BS overlaps with the orthographic projection of the first pattern P1 on the base substrate BS.

In the manufacturing method of the detection substrate provided by the embodiment of the present disclosure, the second pattern P2 overlaps with the first pattern P1, which is beneficial to monitoring the alignment accuracy.

For example, in the manufacturing method of the detection substrate, the first pattern P1 is closer to the base substrate BS than the second pattern P2, and the manufacturing method includes: performing a threshold comparison which includes detecting whether the first boundary distance D1 and the second boundary distance D2 of the first pattern P1 and the second pattern P2 in the direction X are within a first threshold range, and/or detecting whether the third boundary distance D3 and the fourth boundary distance of the first pattern P1 and the second pattern P2 in the direction Y are within a second threshold range, if yes, continuing subsequent processes, otherwise, removing the second pattern and forming a new second pattern; and continuously repeating the step of the threshold comparison for the first pattern P1 and the new second pattern P2.

The Step 3) of detecting whether the pattern P201 and the first pattern P1 meet the requirements described in connection with FIG. 15A to FIG. 15B, and the step 5) of detecting whether the first pattern PA and the second pattern PB in the pattern P12 meet the requirements described in connection with FIG. 19A to FIG. 19C are all the steps of the threshold comparison mentioned here.

For example, in the manufacturing method of the detection substrate, as shown in FIG. 15A to FIG. 15B and FIG. 19A to FIG. 19C, the second pattern P2 is a photoresist pattern.

In the embodiment of the present disclosure, in the description of the product, the second pattern P2 is the structure in the product. For the manufacturing method, the second pattern P2 is a photoresist pattern, and the second pattern P2 in the manufacturing method can be referred to the pattern P201 shown in FIG. 15A and the pattern P12 shown in FIG. 19B.

For example, in the manufacturing method of the detection substrate, the first pattern P1 is formed in the same layer as one component of the photosensitive pixel PXL and/or the marking pixel MPX, and the second pattern P2 is formed in the same layer as another component of the photosensitive pixel PXL and/or the marking pixel MPX.

For example, in the manufacturing method of the detection substrate, the manufacturing method further includes forming the data line DL and forming the gate line GL, forming the photosensitive pixel PXL includes forming the transistor T0, and the gate line GL is connected with the gate electrode GT of the transistor T0, and the data line DL is connected with the source electrode SE of the transistor T0.

For example, as shown in FIG. 23, in the manufacturing method of the detection substrate, the direction X is perpendicular to the extension direction of the data line DL, the alignment mark is an overlay mark (the overlay mark LM1), the first pattern P1 of the overlay mark is in the same layer as the gate line GL, and the data line DL is the second pattern P2. The overlay mark LM1 can be used to monitor the alignment accuracy in the direction X.

For example, as shown in FIG. 23 to FIG. 25, in the manufacturing method of the detection substrate, the direction Y is perpendicular to the extension direction of the gate line GL, the alignment mark is an overlay mark (the overlay mark LM2), the second pattern P2 of the overlay mark is in the same layer as the data line DL, and the gate line GL serves as the first pattern P1. The overlay mark LM2 can be used to monitor the alignment accuracy in the direction Y.

For example, as shown in FIG. 23 to FIG. 25, in the manufacturing method of the detection substrate, the alignment mark MK includes the first alignment mark MK1 (the overlay mark LM1) and the second alignment mark MK2 (the overlay mark LM2), the direction X is perpendicular to the extension direction of the data line DL. The first pattern P1 of the first alignment mark MK1 (the overlay mark LM1) is in the same layer as the gate line GL. The data line DL serves as the second pattern P2 of the first alignment mark MK1 (the overlay mark LM1), the second pattern P2 of the second alignment mark MK2 (the overlay mark LM2) is in the same layer as the data line DL, and the gate line GL serves as the first pattern P1 of the second alignment mark MK2 (the overlay mark LM2).

In the manufacturing method of the detection substrate provided by the embodiment of the present disclosure, by using the gate line GL or the data line DL as a pattern of the alignment mark, the affect on the photosensitive effect of the photosensitive pixel PXL can be avoided, and the display effect can be improved.

For example, as shown in FIG. 15A and FIG. 19B, in the manufacturing method of the detection substrate, the first pattern P1 and the second pattern P2 have a first boundary distance D1 and a second boundary distance D2 in the direction X, the ratio of the first boundary distance D1 to the larger one of the size of the first pattern P1 in the first direction X and the size of the second pattern P2 in the first direction X is less than or equal to ⅓, and the ratio of the second boundary distance D2 to the larger one of the size of the first pattern P1 in the first direction X and the size of the second pattern P2 in the first direction X is less than or equal to ⅓. The second pattern P2 here is the pattern P201 shown in FIG. 15A and/or the pattern P12 shown in FIG. 19B.

For example, as shown in FIG. 15A and FIG. 19B, in the manufacturing method of the detection substrate, the ratio of the first boundary distance D1 to the larger one of the size of the first pattern P1 in the first direction X and the size of the second pattern P2 in the first direction X is larger than or equal to ¼, and the ratio of the second boundary distance D2 to the larger one of the size of the first pattern P1 in the first direction X and the size of the second pattern P2 in the first direction X is larger than or equal to ¼. The second pattern P2 here is the pattern P201 shown in FIG. 15A and/or the pattern P12 shown in FIG. 19B.

For example, as shown in FIG. 15A and FIG. 19B, in the manufacturing method of the detection substrate, the first pattern P1 and the second pattern P2 have a third boundary distance D3 and a fourth boundary distance in the direction Y, the ratio of the third boundary distance D3 to the size of the first pattern P1 in the direction Y is less than or equal to ⅓, and the ratio of the fourth boundary distance D4 to the size of the first pattern P1 in the direction Y is less than or equal to ⅓. The second pattern P2 here is the pattern P201 shown in FIG. 15A and/or the pattern P12 shown in FIG. 19B.

For example, as shown in FIG. 15A and FIG. 19B, in the manufacturing method of the detection substrate, the first pattern P1 and the second pattern P2 have a third boundary distance D3 and a fourth boundary distance in the direction Y, the ratio of the third boundary distance D3 to the size of the first pattern P1 in the direction Y is greater than or equal to ¼, and the ratio of the fourth boundary distance to the size of the first pattern P1 in the direction Y is greater than or equal to ¼. The second pattern P2 here is the pattern P201 shown in FIG. 15A, or the pattern P12 shown in FIG. 19B, or the pattern P12 and the pattern P22 shown in FIG. 19B.

The above are only specific implementations of the present disclosure, the protection scope of the present disclosure is not limited thereto. Any changes or substitutions easily occur to those skilled in the art within the technical scope of the present disclosure should be covered in the protection scope of the present disclosure. Therefore, the protection scope of the present disclosure should be based on the protection scope of the claims.

1. A detection substrate comprising:
a base substrate comprising a pixel setting area; and
a plurality of pixel units, located in the pixel setting area,
wherein the plurality of pixel units comprise a marking pixel, and at least one alignment mark is arranged in the marking pixel.

2. The detection substrate according to claim 1, wherein the alignment mark comprises a first pattern and a second pattern, and an orthographic projection of the second pattern on the base substrate overlaps with an orthographic projection of the first pattern on the base substrate.

3. The detection substrate according to claim 2, wherein the alignment mark comprises an overlay mark,
the first pattern of the overlay mark is a first material layer, and the second pattern of the overlay mark is a second material layer, and materials of the first material layer and the second material layer are different.

4. The detection substrate according to claim 3, wherein a plurality of the overlay marks are arranged in one same marking pixel, materials of the first patterns of the overlay marks are same, and materials of the second patterns of at least two overlay marks among the plurality of overlay marks are different.

5. The detection substrate according to claim 4, wherein the plurality of overlay marks are spaced apart from each other, sequentially arranged in one direction, or arranged in an array in two directions.

6. The detection substrate according to claim 4, comprising a gate layer, an active layer, and a source-drain layer, wherein the active layer is located at a side of the gate layer away from the base substrate, the source-drain layer is located at a side of the active layer away from the base substrate, and the plurality of overlay marks comprise a first overlay mark and a second overlay mark, the first pattern of the first overlay mark is located in the gate layer, the second pattern of the first overlay mark is in a same layer as the active layer, the first pattern of the second overlay mark is located in the gate layer, and the second pattern of the second overlay mark is located in the source-drain layer.

7. The detection substrate according to claim 6, further comprising a first passivation layer, wherein the first passivation layer is located at a side of the source-drain layer away from the base substrate, and the plurality of overlay marks further comprise a third overlay mark, the first pattern of the third overlay mark is located in the gate layer, and the second pattern of the third overlay mark is a via hole in the first passivation layer.

8. The detection substrate according to claim 6, further comprising a first passivation layer, a first electrode layer, a photoelectric sensing layer, a planarization layer, a second passivation layer, a bias voltage line layer, and a third passivation layer that are sequentially arranged, wherein the plurality of overlay marks are located in one same marking pixel, and the plurality of overlay marks further comprise at least one selected from a group consisting of a third overlay mark, a fourth overlay mark, a fifth overlay mark, a sixth overlay mark, a seventh overlay mark, an eighth overlay mark, and a ninth overlay mark,
wherein the plurality of overlay marks comprise the third overlay mark, the fourth overlay mark, the fifth overlay mark, the sixth overlay mark, the seventh overlay mark, the eighth overlay mark, and the ninth overlay mark,
wherein the first patterns of the third overlay mark, the fourth overlay mark, the fifth overlay mark, the sixth overlay mark, the seventh overlay mark, the eighth overlay mark, and the ninth overlay mark are all located in the gate layer,
the second pattern of the third overlay mark is a via hole in the first passivation layer, the second pattern of the fourth overlay mark is located in the first electrode layer, the second pattern of the fifth overlay mark is located in the photoelectric sensing layer, the second pattern of the sixth overlay mark is a via hole in the planarization layer, the second pattern of the seventh overlay mark is a via hole in the second passivation layer, the second pattern of the eighth overlay mark is located in the second electrode layer, and the second pattern of the ninth overlay mark is located in the bias voltage line layer.

9. (canceled)

10. The detection substrate according to claim 2, further comprising a gate line and a data line, wherein at least one of the plurality of pixel units comprises a transistor, the gate line is connected with a gate electrode of the transistor, and the data line is connected with a source electrode of the transistor,
the alignment mark comprises at least one of a first alignment mark and a second alignment mark,
in the first alignment mark, the first pattern is in a same layer as the gate line, and the data line is the second pattern,
in the second alignment mark, the second pattern is in a same layer as the data line, and the gate line is the first pattern.

11. The detection substrate according to claim 10, wherein the alignment mark further comprises a third alignment mark, and an orthographic projection of the second pattern of the third alignment mark on the base substrate is within an orthographic projection of the first pattern of the third alignment mark on the base substrate.

12. The detection substrate according to claim 3, wherein the alignment mark further comprises a stitch mark, the first pattern of the stitch mark is an alignment material layer, and the second pattern of the stitch mark is a hollow area.

13. The detection substrate according to claim 12, wherein the stitch mark comprises a first stitch mark, a second stitch mark and a third stitch mark, the first stitch mark is located in the gate layer, the second stitch mark is in a same layer as the active layer, and the third stitch mark is located in the source-drain layer.

14. The detection substrate according to claim 1, wherein the marking pixel comprises a first marking pixel, the stitch mark is located in the first marking pixel, the marking pixel comprises a second marking pixel, the overlay mark is located in the second marking pixel, and the first marking pixel and the second marking pixel are adjacent to each other.

15-16. (canceled)

17. The detection substrate according to claim 2, wherein an orthographic projection of the second pattern on the base substrate is within an orthographic projection of the first pattern on the base substrate.

18. (canceled)

19. The detection substrate according to claim 2, wherein at least two alignment marks are arranged in one same marking pixel, and the two alignment marks are spaced apart from each other.

20. The detection substrate according to claim 1, wherein the plurality of pixel units comprise a plurality of photosensitive pixels and a plurality of positioning pixels,
wherein at least one marking pixel in the plurality of marking pixels is adjacent to at least one photosensitive pixel in the plurality of photosensitive pixels, and the plurality of marking pixels comprise at least one positioning pixel in the plurality of positioning pixels and/or at least one photosensitive pixel in the plurality of photosensitive pixels.

21. The detection substrate according to claim 20, wherein the plurality of positioning pixels comprise a non-photosensitive pixel,
wherein each of the plurality of positioning pixels is configured to have a fixed gray scale, and the fixed gray scale does not change with real-time change of incident light.

22-26. (canceled)

27. An imaging system, comprising a detector, the detector comprising the detection substrate according to claim 1.

28. A manufacturing method of a detection substrate, comprising:
forming a plurality of pixel units in a pixel setting area of a base substrate, wherein
the plurality of pixel units comprise a marking pixel, and at least one alignment mark is arranged in the marking pixel,
wherein forming the alignment mark comprises:
forming a first pattern and forming a second pattern, wherein an orthographic projection of the second pattern on the base substrate overlaps with an orthographic projection of the first pattern on the base substrate,
wherein the second pattern is a photoresist layer.

29. (canceled)

30. The manufacturing method of the detection substrate according to claim 28, wherein the first pattern is closer to the base substrate than the second pattern,
the manufacturing method comprises:
performing a threshold comparison which comprises: detecting whether a first boundary distance and a second boundary distance of the first pattern and the second pattern in a first direction are within a first threshold range, and/or detecting whether a third boundary distance and a fourth boundary distance of the first pattern and the second pattern in a second direction are within a second threshold range, if yes, continuing subsequent processes, otherwise, removing the second pattern and forming a new second pattern; and
continuously repeating a step of the threshold comparison for the first pattern and the new second pattern,
the manufacturing method further comprises forming a data line and forming a gate line, wherein forming the plurality of pixel units comprises forming a transistor, and the gate line is connected with a gate electrode of the transistor, and the data line is connected with a source electrode of the transistor,
the alignment mark comprises at least one of a first alignment mark and a second alignment mark,
in the first alignment mark, the first pattern is in a same layer as the gate line, and the data line is the second pattern,
in the second alignment mark, the second pattern is in a same layer as the data line, and the gate line is the first pattern.

31-36. (canceled)
